(19) United States
(12) Patent Application Publication
(10) Pub. No.: US 2026/0297723 A1
(43) Pub. Date: Oct. 1, 2026

(54) AL-SC ALLOYS AND SPUTTERING TARGETS AND PROCESSES FOR CONSOLIDATING

(71) Applicant: MATERION CORPORATION, Mayfield Heights, OH (US)

(72) Inventors: Qi ZENG, Mayfield Heights, OH (US); Katharine S. GARDINIER, Mayfield Heights, OH (US); David Peter VANHEERDEN, Mayfield Heights, OH (US); Jens WAGNER, Mayfield Heights, OH (US)

(73) Assignee: MATERION CORPORATION, Mayfield Heights, OH (US)

(21) Appl. No.: 19/475,877

(22) PCT Filed: Apr. 19, 2024
(86) PCT No.: PCT/US2024/025329

§ 371 Date: Oct. 16, 2025

Related U.S. Application Data
(60) Provisional application No. 63/497,406, filed on Apr. 20, 2023.

(51) Int. Cl. C23C 14/34; C22C 21/00

(52) U.S. Cl. CPC C23C 14/3414; C22C 21/00

(57) ABSTRACT

A process for producing an aluminum-scandium alloy sputtering target, the process comprising: atomizing ScₓAl₁₋ₓ to form a powder, wherein x ranges from 0.05 and 0.5; and consolidating the powder to form a target having a microstructure characterized by an average grain size of at most 50 microns. An aluminum-scandium alloy sputtering target comprising one or more Al—Sc intermetallic phases including Al—Sc intermetallic grains, wherein an average Al—Sc intermetallic grain size is at most 50 microns.

### PRIORITY CLAIM

The present application claims priority to U.S. Provisional Application No. 63/497,406, filed on Apr. 20, 2023, the entire contents and disclosure of which is hereby incorporated by reference.

### FIELD

The present disclosure relates to sputtering targets and processes for producing the same. In particular, the process uses powders in a consolidation process that produces a durable aluminum-scandium alloy sputtering targeting suitable for forming a metallic film or a nitride film. In one embodiment, the durable sputtering target is less susceptible to cracking.

### BACKGROUND

Aluminum scandium nitride (AlₓSC₁₋ₓN) is of interest for the fabrication of thin film piezoelectric materials for various applications. Specifically, aluminum scandium nitride (AlScN) thin films produced by reactive sputtering from Al—Sc alloy targets are useful as piezoelectric materials in electro-acoustic applications. For example, AlScN films are used in the manufacture of the bulk acoustic wave (BAW) filters enabling 5G communications. A conventional method for manufacturing these piezoelectric thin films is by using reactive sputter deposition. The sputtering target, typically a metal or metallic alloy, is constructed of the material to be sputtered. The sputtering target and the substrate are placed in proximity to one another within the chamber and the target is bombarded with charged particles or ions. The high energy ions cause a portion of the sputtering target to dislodge and be re-deposited on the substrate. Sputtering is advantageous because it allows compositional control of the film, affords control of residual stresses in the film, allows high rate deposition of the thin film, and readily accommodates controlled heating of the substrate. There is already a strong history of using this process in fabricating thin films.

The resulting properties of the thin films depend strongly on uniform deposition of the Al—Sc alloy. This imposes considerable demands on the properties of the sputtering targets and the alloys. The Al—Sc alloy system presents challenges for the manufacturing of sputter targets due to the presence of multiple brittle intermetallic phases and a propensity for segregation. The piezoelectric response of the thin film is strongly dependent upon the scandium content of the film, and so the overall morphology, microstructure, and chemistry of the scandium in the sputtering target is critical.

Previously, targets comprising the aluminum-scandium alloys suffered from deficiencies in physical/mechanical performance such as a non-uniform microstructure, areas of low density, and/or having defects leading to cracks which can cause arcing and/or particulation during sputtering, leading to yield losses and reduced target lifetime.

Even in view of the known alloys and sputtering targets, the need exists for an uncomplicated, powder consolidating process to produce an Al—Sc alloy sputtering target that provides a uniform and fine microstructure while also providing high density, hardness, and fracture toughness. Targets, such as those described herein, having a uniform and fine microstructure to satisfy the need for targets generating minimal sputtering arcs during magnetron sputtering and hence better performance.

### SUMMARY

In some aspects, the techniques described herein relate to a process of producing an aluminum-scandium alloy sputtering target. The process comprises atomizing ScₓAl₁₋ₓ to form a powder, wherein x ranges from 0.05 and 0.5. The process further comprises consolidating the powder to form a target having a microstructure characterized by an average grain size of at most 50 microns.

In some aspects, the techniques described herein relate to a process for producing an aluminum-scandium alloy sputtering target, the process including: atomizing ScₓAl₁₋ₓ to form a powder, wherein x ranges from 0.25 to 0.45; and consolidating the powder to form a target having an average Al—Sc intermetallic grain size of at most 50 microns. Consolidating may include heating from 900° C. to 1200° C. under pressure by at least one of spark plasma sintering, ultra-high pressure sintering, hot pressing, inert gas hot pressing, and vacuum hot pressing.

In some aspects, the techniques described herein relate to an aluminum-scandium alloy sputtering target including one or more Al—Sc intermetallic phases including Al—Sc intermetallic grains, wherein an average Al—Sc intermetallic grain size is at most 50 microns.

### BRIEF DESCRIPTION OF THE DRAWINGS

A further understanding of the nature and advantages of the disclosed technology may be realized by reference to the remaining portions of the specification and the drawings.

FIG. 1A demonstrates piezoelectric coefficient as a function of Sc content.

FIG. 1B demonstrates mixing enthalpy as a function of Sc content.

FIG. 2 illustrates a schematic of centrifugal gas atomization system.

FIG. 3 illustrates particle size distribution for 30% GA powder.

FIG. 4 illustrates SED-SEM micrographs of as-atomized powders at low and high magnification: (a, d) GA5%, (b, e) GA30%, and (c, f) GA50%.

FIG. 5 illustrates cross-sectional OM (top) and BSE-SEM (bottom) micrographs of as-atomized powders (a, d) GA5%, (b, e) GA30%, and (c, f) GA50%.

FIG. 6 illustrates an Al—Sc binary phase diagram.

FIG. 7 illustrates cross section BSE-SEM image of a GA Sc30% particle with a central pore. Inset image shown DAS was used to calculate cooling rate.

FIG. 8 illustrates x-ray diffraction patterns with Miller indices from GA Sc5%, Sc30% and Sc50% powders.

FIG. 9 illustrates micrographs of comparative as-cast (Sc6%) vs HP (GA Sc5%).

FIG. 10 illustrates BSE-SEM image and corresponding EDS elemental mapping of HP GA Sc50%.

FIG. 11 illustrates a DTA thermogram of GA30% powder.

FIG. 12 illustrates OM micrographs of samples HP 1-4 #. Brown phase is Al₂Sc, white matrix is Al₃Sc.

FIG. 13 illustrates optical and SEM micrograph of HP1 #after 1200° C. heat treatment and water quenched. Indicated phases were confirmed by EDS.

FIG. 14 illustrates X-ray diffraction patterns of 30% Sc samples, a) GA powder, b) as-cast, c) HP at 1100° C., and d) HP+Heat treated at 1200° C.

FIG. 15 illustrates time series plots of process temperature, DC current, ram pressure, and ram position.

FIG. 16 illustrates optical micrographs of SPS samples 1-4 #. Brown phase Al₂Sc, white matrix phase Al₃Sc.

FIG. 17 illustrates an optical micrograph of a spent SPS target showing phase structure according to embodiments herein.

FIG. 18 illustrates an optical micrograph of a spent as-cast comparative target.

FIG. 19 illustrates an electron backscatter diffraction (EBSD) micrograph of a spent SPS target showing grain structure according to embodiments herein.

FIG. 20 illustrates an EBSD micrograph of a spent as-cast comparative target.

FIG. 21 illustrates optical micrographs of Vickers indentation on polished surface for Vickers indent in Al-30% Sc. a) comparative as cast Al₃Sc phase, b) comparative as cast Al₂Sc phase, c) HP3 #, and d) SPS1 #. The white phase is Al₃Sc, brown phase is Al₂Sc phase. Load used=1 kg. Note scale bar length difference.

FIG. 22 illustrates SED-SEM fracture surface of the sample SPS 4 #, a) low, b) high-magnification, showing cleavage steps and river patterns, and c) micrograph of SPS+quenched cracking.

FIG. 23 illustrates spent targets from a) comparative as-cast, b) SPS4 #, and c) HP 3 #

FIG. 24 illustrates optical micrographs of SPS 4 #target after 12 hr sputtering. a) in the track area, b) outside track area.

FIG. 25 illustrates optical micrographs of spent targets. A) comparative as cast, b) SPS 4 #, and c) HP 3 #.

FIG. 26 illustrates an X-ray diffraction pattern for a HP AlSc35% target according to embodiments herein.

FIG. 27 illustrates an X-ray diffraction pattern for an as-cast 35% Sc comparative target.

FIG. 28 illustrates an optical micrograph for an as-cast 35% Sc comparative target.

### DETAILED DESCRIPTION

### Introduction

As discussed above, previous Al—Sc alloy sputtering targets suffer from problems due to non-uniform microstructures and/or defects, e.g., cracks due to challenges associated with brittle (intermetallic) phase(s) common to the Al—Sc alloys.

It has now been discovered that the disclosed processes synergistically combine to provide for a uniform, fine microstructure that has the desired high hardness and fracture toughness. To achieve the desired microstructure, Al—Sc alloys are atomized to form powders for consolidating. Surprisingly, it has been found that atomization provides a predominance of preferred phases, e.g., Al₃Sc rather than Al₂Sc (contrary to the phases expected according to available binary Al—Sc phase diagrams) in targets having scandium content of about 30 at %. Advantageously, the atomized powders herein comprise spherical particles having a fine average size as well as a narrow particle size distribution. Processes herein further include that the atomized powders are consolidated by hot pressing and/or spark plasma sintering to form dense, sintered sputtering targets of high fracture toughness and uniform phase distribution.

Sputtering targets made from the processes herein may be used to deposit thin films onto a substrate. The piezoelectric properties of an individual device on the substrate are critically dependent upon the local stoichiometry of the film contained within an individual device. Hence the distribution of the scandium and/or scandium-containing phases through an Al—Sc sputtering target should be as finely distributed and as uniform as possible. This is important because if the amount of scandium being sputtered from the target varies over the life of the target, the piezoelectric properties of the deposited film will change over the life of the target, resulting in device performance inconsistencies and resulting product yield loss. Further, it has been found that certain intermetallic phases are preferred (e.g., Al₃Sc) over others (e.g., Al₂Sc) imparting certain favorable properties such as fracture toughness (e.g., resistance to cracking). Thus, evenly distributed phases within the target microstructure is also necessary to provide targets for long life and high performance (crack resistant, minimal arcing behavior, and minimal particulation). Processing, as well as properties and characteristics, of the sputtering targets are discussed below.

### Piezoelectric Materials in Electro-Acoustic Applications

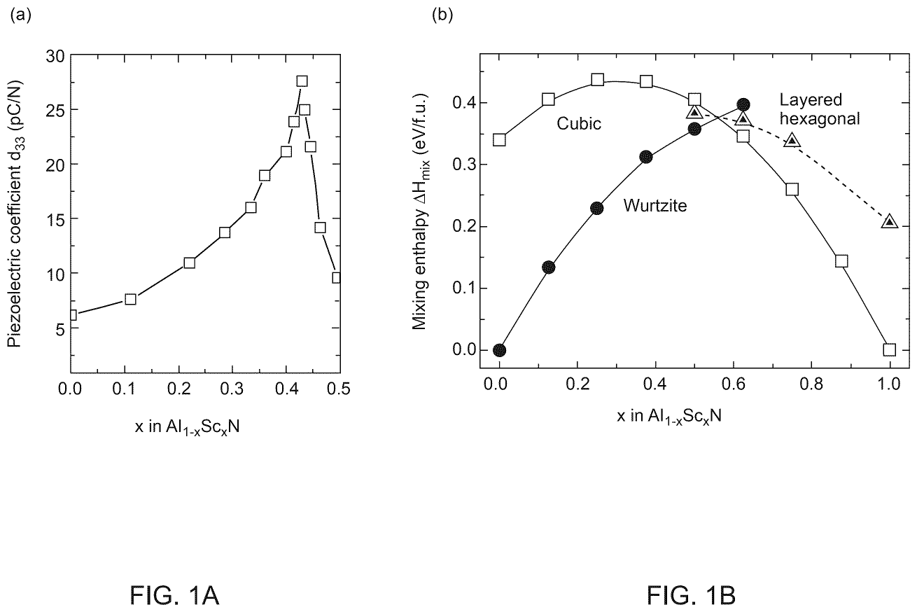

One of the piezoelectric materials in electro-acoustic applications is aluminum nitride (AlN). However, AlN-based devices have a rather low piezoelectric coefficient d₃₃=5.5 pC/N, and a limited electromechanical coupling of 7%. These properties are significantly improved by adding scandium (Sc) in the wurtzite structure AlN. It was shown that the incorporation of Sc into AlN allows an increase up to 400% of the piezoelectric coefficient d₃₃ (FIG. 1A). Moreover, the material electromechanical coupling of the Al₁₋ₓSCₓN is expected to increase 200% with Sc concentration x=0.3. The piezoelectric AlScN will remain the same hexagonal wurtzite structure as AlN with c-axis orientation up to x=0.5 (FIG. 1B), so that the max doping Sc in Al₁₋ₓScₓN could be up to 50%.

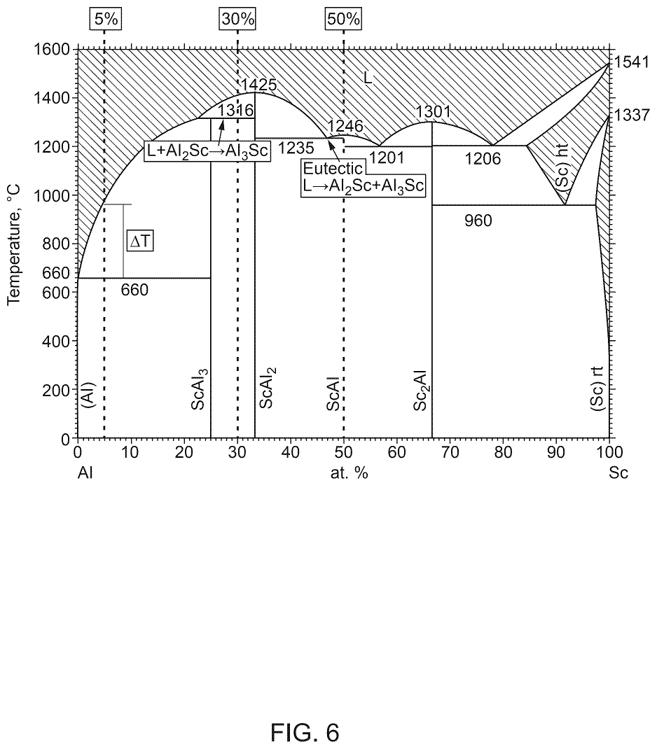

AlScN thin films are normally produced by reactive sputtering from AlSc alloy targets. The extrinsic properties required of any AlScN thin film are similar: the deposit should be homogeneous in chemistry, exhibit consistent metallurgical structure, be uniform in thickness, and adequately coat all feature on the substrate. The sputtering performance of AlSc targets must be predictable and consistent: performance must not vary significantly through the life of the target, nor should be sputtering reliability deviate from target to target. AlSc sputtering targets themselves refer to the bulk material that is deposited onto a substrate with mainly being manufactured through casting method. The quality of deposited film is directly affected by the quality of the target that has been cast, with common defects being porosity, non-homogeneity of both composition and microstructure due to a large solidification temperature range (ΔT up to 640° C.) in Al—Sc system (<25 at % Sc, see FIG. 6), and to a great difference between the melting temperatures of Sc and Al. Impurities and oxides are other general concerns. The composition of these targets plays a huge role in the success of the sputtering process, and therefore the overall viability of the filter itself. Impurities are a common detrimental component that target material often contains as it tends to dampen the piezoelectric effect of the Al—Sc alloy. Another common defect seen in target material is porosity. During sputtering, porosity can prevent uniform deposition rates as well as result in particulation.

Powder metallurgy (PM) is a relevant alternative route to product large sized (diameter) targets, which offers the potential for minimizing porosity and non-uniformity of composition and microstructure, and potentially for reducing overall cost of the final targets made by conventional ingot metallurgy.

However, oxygen control is a big challenge with the powder approach. Elemental Al and Sc powders as well as aluminum scandium intermetallics are very reactive and as a result the particle surface is easily oxidized forming a surface oxide film that poses certain technological challenges. Hot pressing in vacuum or hydrogen atmosphere could solve problem to some degree, but it is not expected that vacuum or hydrogen can remove most of oxygen if stable Al₂O₃ or Sc₂O₃ oxide is formed. More recently, the technology of SPS has emerged as a new means to overcome the surface film constraint. This process typically applies a high amperage DC current and uniaxial pressure simultaneously to compact and sinter the powder. Unlike conventional sintering, the SPS process affords rapid heating rates and reduced sintering temperatures that suppress microstructural coarsening. It has been demonstrated that the surface oxides at interparticle contact points can be mitigated by SPS. Any semicontinuous network of residual oxide phase in the sintered product is undesirable as it can be detrimental to ductility.

### Experimental Methods

Some details regarding exemplary experimental methods are provided herein. The provision of these example is not intended to be (and is not) limiting.

Microstructural Analysis. In some cases, microstructure and the morphologies of the powders are characterized by either an optical microscopy (OM, Keyence VHX-970F) and scanning electron microscopy (SEM, JEOL JSM-IT500). Cross sections of GA powders and pressed samples may be mounted, ground and polished with a final 1200 grit silicon carbide disk, and subsequently polished in stages using cloth pads and diamond suspensions from 9, 6, 3, and 1 micron, before finishing with 0.06 microns colloidal silica suspension. Electron Backscatter Diffraction (EBSD) is also used in JEOL IT800 to analyze the microstructure. The microstructure may be characterized by phases present and/or by average grain size. Phases present (e.g., intermetallic Al—Sc phases) may be determined by a combination of microscopic imaging, image analysis, and X-ray diffraction techniques. Average grain size is determined by ASTM E112-13.

Hardness. Hardness measurements may be made using a Wilson VH1202 Vickers hardness tester operated with an applied load of 0.05 kg, 0.3 kg, 1 kg, 2 kg average hardness—readings may be determined from five measurements. The fracture toughness values may be calculated from indentation dimensions and indentation-tip crack length measurements according to ASTM E384 standard test method.

Conductivity. Eddy current electrical conductivity may be tested with a Sigmascope SMP350-Fisher.

Phase Transformation. A differential Thermal Analysis (DTA) run may be conducted using a Perkin Elmer DTA system 1700 in Ar from room temperature to 1250° C. at a constant heating and cooling rate of 20° C./min.

Density. Densities of samples may be measured by hydrostatic weighing in distilled water using an analytical balance. Density accuracy is +/−0.02 g/cc.

X-ray Diffraction. Phase analysis and microstructural characterization may be determined via X-ray diffraction (XRD) using Cu-Kα radiation (λ=0.15406 nm) in the 20 range of 20-75°. An angular step size of 0.02 degrees and counting time of 11 s/step may be used. Since all phases involved, Al(fcc), Al₃Sc(L1₂), Al₂Sc(C15), AlSc(B₂), have a cubic structure, d-spacing formula below holds,

$$\frac{1}{{d}^{2}} = \frac{{h}^{2} + {k}^{2} + {l}^{2}}{{a}^{2}} \qquad ( 2 - 1 )$$

And per Bragg's law,

$${d}_{h , k , l} = \frac{λ}{2 sin θ} \qquad ( 2 - 2 )$$

So, combining Eqs. (2-1) and (2-2), the lattice parameter, α, is calculated by

$$a = \frac{λ}{2 sin θ} \sqrt{( {h}^{2} + {k}^{2} + {l}^{2} )} \qquad ( 2 - 3 )$$

After indexing all diffraction peaks, each peak is used to calculate one value of a, the final lattice parameter may be estimated as the average of all values.

### Processes

The disclosure relates to processes for producing Al—Sc alloy sputtering targets. The process comprises atomizing ScₓAl₁₋ₓ to form a powder, wherein x ranges from 0.05 and 0.5, and consolidating the powder to form a target.

Atomizing. Atomizing may be conducted via centrifugal helium atomization as detailed in the examples below. Atomizing may include the powder being of one or more phases. For Al-30% Sc, in some embodiments, atomizing may include the powder having an Al₃Sc/(Al₃Sc+Al₂Sc) ratio of at least 0.5. The processes herein include that wherein x ranges from 0.25 to 0.33, atomizing includes that the powder has a higher Al₃Sc/(Al₃Sc+Al₂Sc) ratio than as-cast products, as is detailed in the examples below. In some embodiments where x ranges from 0.25 to 0.33, the powder comprises an Al₃Sc/(Al₃Sc+Al₂Sc) ratio of at least 0.5, e.g., at least 0.55, at least 0.60, at least 0.62, at least 0.63, at least 0.64, or at least 0.65. More specifically and unexpectedly (in view of the phase diagram at FIG. 6), where x ranges from 0.29 to 0.33, the powder comprises an Al₃Sc/(Al₃Sc+Al₂Sc) ratio of at least 0.5. In other words, the atomized powder includes more Al₃Sc than Al₂Sc. Unless otherwise noted, ratios may be determined on an XRD peak integral intensity basis for the Al—Sc intermetallic phases. As understood herein, atomizing a powder may further include milling and or crushing the powder to reduce particle size prior to consolidating.

Consolidating. Consolidating includes inert gas or vacuum hot pressing and/or spark plasma sintering as detailed in the examples below. For Al-30% Sc, consolidating may include the target having an Al₃Sc/(Al₃Sc+Al₂Sc) ratio of at least 0.5 (as exemplified in Table 6 below). In some embodiments, the target comprises an Al₃Sc/(Al₃Sc+Al₂Sc) ratio of at least 0.5, e.g., at least 0.55, at least 0.60, at least 0.62, at least 0.63, at least 0.64, or at least 0.65. In some embodiments where x ranges from 0.25 to 0.33, the target comprises an Al₃Sc/(Al₃Sc+Al₂Sc) ratio of at least 0.5, e.g., at least 0.55, at least 0.60, at least 0.62, at least 0.63, at least 0.64, or at least 0.65. More specifically, where x ranges from 0.29 to 0.33, the target comprises an Al₃Sc/(Al₃Sc+Al₂Sc) ratio of at least 0.5.

Hot pressing may include heating (e.g., sintering to provide densification) to certain temperatures, times, and at certain pressures. Hot pressing may include inert gas hot pressing (IGHP) and hot isostatic pressing (HIP). In some embodiments, hot pressing is at a temperature of from 900° C. to 1250° C., e.g., from 1000° C. to 1225° C., from 1050° C. to 1250° C., or 1100° C. to 1250° C. In terms of lower limits, hot pressing may at be conducted a temperature of at least 900° C., e.g., at least 950° C., at least 1050° C., or at least 1100° C. In terms of upper limits, hot pressing may at be conducted a temperature of at most 1250° C., e.g., at most 1225° C., at most 1200° C., or at most 1150° C.

In some embodiments, hot pressing is at a time of from 1 hour to 8 hours, e.g., from 1 hour to 4 hours, from 2 hours to 6 hours or from 3 hours to 5 hours. In terms of lower limits, hot pressing may at be conducted a time of at least 1 hour, e.g., at least 2 hours or at least 3 hours. In terms of upper limits, hot pressing may at be conducted a time of at most 8 hours, e.g., at most 6 hours, at most 5 hours, or at most 4 hours. In certain embodiments, hot pressing is at a time of 4 hours.

In some embodiments, hot pressing is at a pressure of from 10 MPa to 60 MPa, e.g., from 10 MPa to 50 MPa, or from 15 MPa to 45 MPa. In terms of lower limits, hot pressing may at be conducted a pressure of at least 10 MPa, e.g., at least 15 MPa or at least 25 MPa. In terms of upper limits, hot pressing may at be conducted a pressure of at most 60 MPa, e.g., at most 50 MPa, at most 45 MPa, or at most 35 MPa. In certain embodiments, hot pressing is at a pressure of 15 MPa. In other embodiments, hot pressing is at a pressure of 45 MPa.

Hot pressing may be conducted in an inert atmosphere, e.g., in Ar gas.

Spark plasma sintering may include heating (e.g., sintering to provide densification) to certain temperatures, times, and at certain pressures. Ultra-high pressure sintering may also be used. In some embodiments, spark plasma sintering is at a temperature of from 900° C. to 1250° C., e.g., from 900° C. to 1200° C., from 950° C. to 1150° C., from 1000° C. to 1200° C., or from 1000° C. to 1100° C. In terms of lower limits, spark plasma sintering may at be conducted at a temperature of at least 900° C., e.g., at least 950° C., at least 1000° C., at least 1050° C., or at least 1100° C. In terms of upper limits, spark plasma sintering may at be conducted a temperature of at most 1250° C., e.g., at most 1100° C., at most 1150° C., or at most 1100° C.

In some embodiments, spark plasma sintering is at a time of from 1 minute to 60 minutes (1 hour), e.g., from 5 minutes to 60 minutes, from 10 minutes to 40 minutes or from 15 minutes to 30 minutes. In terms of lower limits, spark plasma sintering may at be conducted a time of at least one minute, e.g., at least 5 minutes, at least 10 minutes, or at least 15 minutes. In terms of upper limits, spark plasma sintering may at be conducted a time of at most 1 hour, e.g., at most 40 minutes or at most 30 minutes. In certain embodiments, spark plasma sintering is at a time of 10 minutes or 22 minutes or 40 minutes.

In some embodiments, spark plasma sintering is at a pressure of from 35 MPa to 75 MPa, e.g., from 45 MPa to 65 MPa. In terms of lower limits, spark plasma sintering may at be conducted a pressure of at least 35 MPa, e.g., at least 45 MPa or at least 55 MPa. In terms of upper limits, spark plasma sintering may at be conducted a pressure of at most 75 MPa, e.g., at most 65 MPa or at most 55 MPa. In certain embodiments, spark plasma sintering is at a pressure of 45 MPa. In other embodiments, spark plasma sintering is at a pressure of 55 MPa. In yet other embodiments, spark plasma sintering is at a pressure of 65 MPa.

Spark plasma sintering may be conducted in an inert atmosphere, e.g., in Ar gas, or in a vacuum, or in a forming gas. In certain embodiments, the process herein includes consolidating the powder to form an aluminum-scandium alloy sputtering target via spark plasma sintering at one or more of: a temperature from 1000° C. to 1200° C.; a time of from 1 minute to 60 minutes; and a pressure of from 35 MPa to 75 MPa.

Target Composition. In some embodiments, the Al—Sc targets contain from 5 at % to 50 at % scandium and from 50 at % to 95% aluminum (optionally along with other elements). For example, in ScₓAl₁₋ₓ wherein x equals 0.05 means the alloy comprises 5 at % scandium and 95 at % aluminum. In another example, in ScₓAl₁₋ₓ wherein x equals 0.3 means the alloy comprises 30 at % scandium and 70 at % aluminum. In yet another example, in ScₓAl₁₋ₓ wherein x equals 0.5 means the alloy comprises 50 at % scandium and 50 at % aluminum. Further compositional details are provided below. The atomized and crushed and/or milled powder composition determines the target composition.

Overall, the process for producing includes Al—Sc targets comprising ScₓAl₁₋ₓ wherein x ranges from 0.05 and 0.5, e.g., x ranges from 0.05 to 0.50, from 0.10 to 0.50, from 0.08 to 0.45, from 0.15 to 0.45, from 0.25 to 0.45, from 0.20 to 0.40, from 0.05 to 0.10, from 0.10 to 0.15, from 0.15 to 0.20, from 0.20 to 0.25, from 0.25 to 0.30, from 0.30 to 0.35, from 0.35 to 0.40, from 0.40 to 0.45, or from 0.45 to 0.50. In certain embodiments, In terms of lower limits, the Al—Sc sputtering target may comprise x=at least 0.05, e.g., at least 0.08, at least 0.10, at least 0.15, at least 0.20, at least 0.25, at least 0.30, at least 0.35, at least 0.40, or at least 0.45. In terms of upper limits, the Al—Sc sputtering target may comprise x=at most 0.5, e.g., at most 0.50, at most 0.45, at most 0.40, at most 0.35, at most 0.30, at most 0.25, at most 0.20, at most 0.15, or at most 0.10. In certain aspects, x is equal to 0.30; or x is equal to 0.35; or x is equal to 0.38; or x is equal to 0.42.

Overall, the disclosed Al—Sc alloy sputtering target, in some embodiments, comprises from 5 at % to 50 at % scandium, e.g., from 10 at % to 50 at %, from 5 at % to 45 at %, from 8 at % to 45 at %, from 15 at % to 45 at %, from 25 at % to 45 at %, from 20 at % to 40 at %, from 5 at % to 10 at %, from 10 at % to 15 at %, from 15 at % to 20 at %, from 20 at % to 25 at %, from 25 at % to 30 at %, from 30 at % to 35 at %, from 35 at % to 40 at %, from 40 at % to 45 at %, or from 45 at % to 50 at %.

In terms of lower limits, the Al—Sc sputtering target may comprise at least 5 at % scandium, e.g., at least 8 at %, at least 10 at %, at least 15 at %, at least 20 at %, at least 25 at %, at least 30 at %, at least 35 at %, at least 40 at %, or at least 45 at %. In terms of upper limits, the sputtering target may comprise at most 50 at % scandium, e.g., at most 45 at %, at most 40 at %, at most 35 at %, at most 30 at %, at most 25 at %, at most 20 at %, at most 15 at %, or at most 10 at %.

Overall, the disclosed Al—Sc alloy sputtering target having scandium contents as above, in some embodiments, comprises a balance of aluminum, e.g., from 50 at % to 95 at % aluminum. In terms of lower limits, the Al—Sc sputtering target may comprise at least 50 at % aluminum, e.g., at least 55 at %, at least 60 at %, at least 65 at %, at least 70 at %, at least 75 at %, at least 80 at %, at least 85 at %, or at least 90 at %. In terms of upper limits, the sputtering target may comprise at most 95 at % aluminum, e.g., at most 90 at %, at most 85 at %, at most 80 at %, at most 75 at %, at most 70 at %, at most 65 at %, at most 60 at %, or at most 55 at %.

### Target Microstructure

The disclosed Al—Sc alloy sputtering target has a microstructure characterized by a fine microstructure and a uniform distribution of phases. Both of these characteristics provide for a target having high fracture toughness and a durable sputtering target that is less susceptible to cracking. The fine microstructure is shown in the Examples herein, where the intermetallic phase(s) have an average grain size of at most 10 microns. Importantly, the grain size of the fine microstructure of the targets produced by processes herein is ten times finer than for convention, as-cast targets.

The aluminum-scandium alloy sputtering target disclosed herein may have an average grain size ranging from 0.1 microns to 10 microns. In some embodiments, the aluminum-scandium alloy sputtering target is characterized as having an average grain size ranging from 0.1 microns to 10 microns, e.g., from 0.5 microns to 10 microns, from 1 micron to 10 microns, from 1 micron to 5 microns, or from 2 microns to 4 microns. In certain aspects, the aluminum-scandium alloy sputtering target disclosed herein may have an average grain size ranging from 1 microns to 5 microns or from 2 microns to 4 microns.

In terms of lower limits, the aluminum-scandium alloy sputtering target may be characterized as having an average grain size at least 0.1 microns, e.g., at least 0.5 microns, at least 1 microns, or at least 2 microns. In terms of upper limits, the aluminum-scandium alloy sputtering target is characterized as having an average grain size at most 10 microns, e.g., at most 8 microns, at most 6 microns, or at most 5 microns.

Further, the distribution of intermetallic phase(s) is uniform in the aluminum-scandium alloy sputtering targets of the processes herein. The fine microstructure is evident in the Examples herein, where the intermetallic phase(s) are evenly distributed. In some embodiments, a first Al—Sc intermetallic phase and a second Al—Sc intermetallic phase are each distributed in phase regions that are at most 10 microns in diameter. The evenly distributed phases are shown in the microstructure via in optical microscopy and/or scanning electron microscopy and image analysis. The intermetallic phases may be interconnected, such that the region size is estimated for an equivalent spherical diameter where the phase regions are multi-granular and non-spherical.

The aluminum-scandium alloy sputtering targets disclosed herein may have a first Al—Sc intermetallic phase and a second Al—Sc intermetallic phase each distributed in phase regions that are at most 10 microns in diameter. In some embodiments, the aluminum-scandium alloy sputtering target is characterized as having uniform distribution of intermetallic phases ranging from 1 microns to 20 microns, e.g., from 1 microns to 10 microns, from 4 microns to 10 microns, or from 5 micron to 8 microns. In certain aspects, the aluminum-scandium alloy sputtering targets herein may have a intermetallic phase each distributed in phase regions that are at most 10 microns in diameter.

The aluminum-scandium alloy sputtering targets having 25% scandium or more disclosed herein may comprise one or more Al—Sc intermetallic phases. In some embodiments, the target comprises Al₃Sc and Al₂Sc. In some embodiments, the target consists of Al₃Sc and Al₂Sc. In some embodiments, the target comprises AlSc and Al₂Sc. In some embodiments, the target consists of AlSc and Al₂Sc. In some embodiments, no phases other than the Al—Sc intermetallic phases are present.

The targets herein may be devoid of or substantially devoid of Al₂O₃. The targets herein may be devoid of or substantially devoid free aluminum (Al). Devoid of or substantially devoid means that aluminum oxide or aluminum metal is not added and it is expressly avoided. In some instances, aluminum oxide or aluminum are present in trace amounts, e.g., less than 5 wt % based on total weight of the target, less than 3 wt % based on total weight of the target, or less than 1 wt % based on total weight of the target. In some instances, any presence of aluminum oxide or aluminum is below the limit of detection, e.g., less than 3 wt % as measured by X-ray diffraction.

The aluminum-scandium alloy sputtering targets disclosed herein may be characterized by a microstructure that includes a crystallographic texture that is isotropic. The isotropic texture may be determined by X-ray diffraction. In other words, the organization of the grains of the microstructure of the disclosed targets is random and no favored planes are identified during analysis. By comparison, and as shown in the Examples, an as-cast target has grains that are organized and is characterized as anisotropic.

### Atomized Powder Properties

Powder Composition. The disclosed atomized powder composition for processes herein, in some embodiments, comprises ScₓAl₁₋ₓ wherein x ranges from 0.05 and 0.5, e.g., x ranges from 0.05 to 0.50, from 0.10 to 0.50, from 0.08 to 0.45, from 0.15 to 0.45, from 0.25 to 0.45, from 0.20 to 0.40, from 0.05 to 0.10, from 0.10 to 0.15, from 0.15 to 0.20, from 0.20 to 0.25, from 0.25 to 0.30, from 0.30 to 0.35, from 0.35 to 0.40, from 0.40 to 0.45, or from 0.45 to 0.50. In certain embodiments, In terms of lower limits, the Al—Sc sputtering target may comprise x=at least 0.05, e.g., at least 0.08, at least 0.10, at least 0.15, at least 0.20, at least 0.25, at least 0.30, at least 0.35, at least 0.40, or at least 0.45. In terms of upper limits, the Al—Sc sputtering target may comprise x=at most 0.5, e.g., at most 0.50, at most 0.45, at most 0.40, at most 0.35, at most 0.30, at most 0.25, at most 0.20, at most 0.15, or at most 0.10. In certain aspects, x is equal to 0.30; or x is equal to 0.35; or x is equal to 0.38; or x is equal to 0.42.

The disclosed atomized powder composition for processes herein, in some embodiments, comprises from 5 at % to 50 at % scandium, e.g., from 10 at % to 50 at %, from 5 at % to 45 at %, from 8 at % to 45 at %, from 15 at % to 45 at %, from 25 at % to 45 at %, from 20 at % to 40 at %, from 5 at % to 10 at %, from 10 at % to 15 at %, from 15 at % to 20 at %, from 20 at % to 25 at %, from 25 at % to 30 at %, from 30 at % to 35 at %, from 35 at % to 40 at %, from 40 at % to 45 at %, or from 45 at % to 50 at %. In terms of lower limits, the powder may comprise at least 5 at % scandium, e.g., at least 8 at %, at least 10 at %, at least 15 at %, at least 20 at %, at least 25 at %, at least 30 at %, at least 35 at %, at least 40 at %, or at least 45 at %. In terms of upper limits, the powder may comprise at most 50 at % scandium, e.g., at most 45 at %, at most 40 at %, at most 35 at %, at most 30 at %, at most 25 at %, at most 20 at %, at most 15 at %, or at most 10 at %. The powder composition can be the same as any of the target compositions as detailed above.

Powder Particle Size. The atomized Al—Sc powder may be crushed and/or milled to reduce particle size. The atomized Al—Sc powder disclosed herein may have a particle size ranging from 2 microns to 300 microns. The powder particles are not single crystal; they are particle agglomerates made of many grains.

In some embodiments, the atomized Al—Sc powder is characterized as having an average particle size ranging from 2 microns to 300 microns, e.g., from 10 microns to 250 microns, from 10 microns to 150 microns, from 50 microns to 225 microns, or from 100 microns to 200 microns. In certain aspects, the atomized Al—Sc powder disclosed herein may have a particle size ranging from 100 microns to 200 microns.

In terms of lower limits, the atomized Al—Sc powder may be characterized as having an average particle size at least 2 microns, e.g., at least 10 microns, at least 50 microns, or at least 100 microns. In terms of upper limits, the powder is characterized as having an average particle size at most 300 microns, e.g., at most 250 microns, at most 225 microns, at most 200 microns, or at most 150 microns.

Powder Particle Size Distribution. The atomized powder has a narrow particle size distribution. This is believed to provide a uniform distribution of phases in the subsequently consolidated sputtering target. The atomized Al—Sc powder disclosed herein may have a particle size distribution, D₅₀, ranging from 50 microns to 150 microns. In some embodiments, the powder is characterized as having a particle size distribution, D₅₀, ranging from 50 microns to 150 microns, e.g., from 60 microns to 140 microns, from 80 microns to 120 microns, or from 90 microns to 100 microns. In certain aspects, the atomized Al—Sc powder disclosed herein may have a particle size distribution, D₅₀, ranging from 90 microns to 100 microns.

Powder Shape and Internal Pores. The atomized Al—Sc powder disclosed herein may comprise spherical particles. Spherical particles demonstrate good flowability. In some embodiments, the spherical particles of the atomized powder useful in the processes herein include porosity and an internal (or central) pores.

Impurity content. In some cases, the Al—Sc sputtering target is of high purity, and contains as few contaminants as possible. For example, oxygen can be extremely deleterious to the properties of piezoelectric films, both by preferentially binding into the matrix and by stabilizing other, non-piezoelectric phases. Thus, the atomized Al—Sc powder disclosed in processes herein should contain as little oxygen as possible. Oxygen is a function of scandium content; thus, the higher the scandium content, the higher the oxygen content. For Al-30% Sc powder, In some embodiments, the powder comprises at most 2000 ppm oxygen, e.g., at most 1750 ppm, at most 1500 ppm, at most 1250 ppm, at most 1000 ppm, at most 600 ppm, or at most 300 ppm.

The presence of transition metal elements, for example iron, should also be minimized. Thus, the atomized Al—Sc powder disclosed in processes herein should contain as little metallic impurities as possible. In some embodiments, the powder comprises at most 2000 ppm metallic impurities, e.g., at most 1750 ppm, at most 1500 ppm, at most 1250 ppm, at most 1000 ppm. at most 750 ppm, or at most 500 ppm

In certain aspects, the atomized powder comprises at most 1000 ppm oxygen, or at most 600 ppm, or at most 300 ppm. In certain aspects, the atomized powder comprises at most 500 ppm transition metal elements. During consolidation processes, the oxygen content may increase. In certain aspects, the aluminum-scandium alloy sputtering target comprises at most 2000 ppm oxygen, at most 1000 ppm oxygen, or at most 600 ppm, or at most 300 ppm.

### Target Phases.

Upon consolidation, the Al—Sc sputtering target has a composition comprising from 5 at % to 50 at % scandium and from 50 at % to 95% aluminum (optionally along with other elements). as detailed above. The sputtering target composition is consistent with the composition of the atomized powder used for consolidating. Sputtering targets as disclosed herein may contain free aluminum (Al), Al₃Sc, Al₂Sc, AlSc, combinations thereof, and possibly trace other phases. Sputtering targets as disclosed herein may be devoid or substantially devoid of Al₂O₃.

In certain embodiments, the Al—Sc sputtering target has a composition ScₓAl₁₋ₓ where x=0.05. The phases present in the target comprising, for example, 5 at % scandium (and balance aluminum) include (predominantly) free aluminum (Al) and the intermetallic phase Al₃Sc.

In other certain embodiments, the Al—Sc sputtering target has a composition ScₓAl₁₋ₓ where x=0.3. The phases present in the target comprising, for example, 30 at % scandium (and balance aluminum) include (predominantly) the intermetallic phases Al₃Sc and Al₂Sc. In preferred embodiments, the Al—Sc sputtering target comprises at least 50% Al₃Sc by intensity as determined by x-ray diffraction. Thus Al₃Sc is the major phase in the target where x=0.3.

The Al₃Sc (L1₂) phase is preferred over Al₂Sc (Laves) at least in part due to its characteristic equiaxed structure rather than the dendritic structure of the Al₂Sc (more prone to brittleness and cracking).

In yet other embodiments, the Al—Sc sputtering target has a composition ScₓAl₁₋ₓ where x=0.5. The phase present in the target comprising, for example, 50 at % scandium (and balance aluminum) include (predominantly) AlSc.

### Target Properties (Al-30% Sc)

Density. Al—Sc sputtering targets of the processes disclosed herein are dense, sintered targets. Densities are dependent upon target composition. In embodiments having Al-30% Sc, targets disclosed herein have a density at least 2.9 g/cm³. Theoretical density is 3.03 g/cm³. In some embodiments, the target has a density at least 2.9 g/cm³, e.g., at least 2.95 g/cm³, at least 2.98 g/cm³, at least 2.99 g/cm³, at least 3.00 g/cm³, or at least 3.03 g/cm³. In some embodiments, the target has a density at least 97% of theoretical density, e.g., at least 98% of theoretical density, at least 99% of theoretical density, at least 99.5% of theoretical density, at least 99.9% of theoretical density, or at least 100% of theoretical density.

Impurity content. As mentioned above, the Al—Sc sputtering target is of high purity, and contains as few contaminants as possible. Thus, the target disclosed in processes herein should contain as little oxygen as possible. In some embodiments, the target comprises at most 2000 ppm oxygen, e.g., at most 1750 ppm, at most 1500 ppm, at most 1250 ppm, or at most 1000 ppm.

The presence of transition metal elements, for example iron, should also be minimized. Thus, the target disclosed in processes herein should contain as little metal elements as possible. In some embodiments, the powder comprises at most 2000 ppm metal elements, e.g., at most 1750 ppm, at most 1500 ppm, at most 1250 ppm, at most 1000 ppm, at most 750 ppm, or at most 500 ppm.

In certain aspects, the target comprises at most 1000 ppm oxygen. In certain aspects, the target comprises at most 500 ppm transition metal elements.

Hardness. Al—Sc sputtering targets of the processes disclosed herein are hard. Hardness is also dependent upon target composition. Hardness will be lower for targets where x low (low Sc content) due to higher Al content (ductile phase). In some embodiments, the targets here demonstrate a hardness of at least 340 HV. Targets of processes herein, in some embodiments, demonstrate a hardness value from 340 HV to 400 HV, e.g., from 345 HV to 390 HV or from 350 HV to 380 HV. In terms of lower limits, the target may demonstrate a hardness at least 340 HV, e.g., at least 345 HV or at least 350 HV. In terms of upper limits, the target may demonstrate a hardness value at most 400 HV, e.g., at most 390 HV or at most 380 HV.

Dimensions. Al—Sc sputtering targets of the processes disclosed herein may be large, e.g., having a diameter of at least 50 mm, at least 100 mm, at least 200 mm, at least 300 mm, at least 400 mm, or at least 450 mm. Thicknesses of the targets herein may be at least 5 mm, at least 8 mm, or at least 10 mm. In certain embodiments, the target of the process herein has a diameter of at least 100 mm and a thickness of at least 8 mm.

For the purposes of examples herein, “as-cast” or “casting” refer to comparative examples made by conventional means. Powder metallurgy (PM), gas atomized (GA), hot presses (HP), and spark plasma sintering (SPS) refer to inventive examples herein.

In some embodiments, any or some of the components disclosed herein may be considered optional. In some cases, the disclosed compositions may expressly exclude any or some of the aforementioned components or process steps in this description, e.g., via claim language. For example claim language may be modified to recite that the disclosed compositions do not utilize or comprise one or more of the aforementioned impurities or phases, e.g., the claim language may be modified to recite that the disclosed targets do not comprise Al₂Sc phase. Such negative limitations are contemplated, and this text serves as support for negative limitations for components, steps, and/or features.

As used herein, “at least” and “at most” limits may also include the number associated therewith. Stated another way, “at least” and “at most” may be interpreted as “at least or equal to” and “at most or equal to.” It is contemplated that this language may be subsequently modified in the claims to include “or equal to.” For example, “at least 1.0 mm” may be interpreted as, and subsequently modified in the claims as “at least or equal to 1.0 mm.”

### Examples

### Materials and Procedures

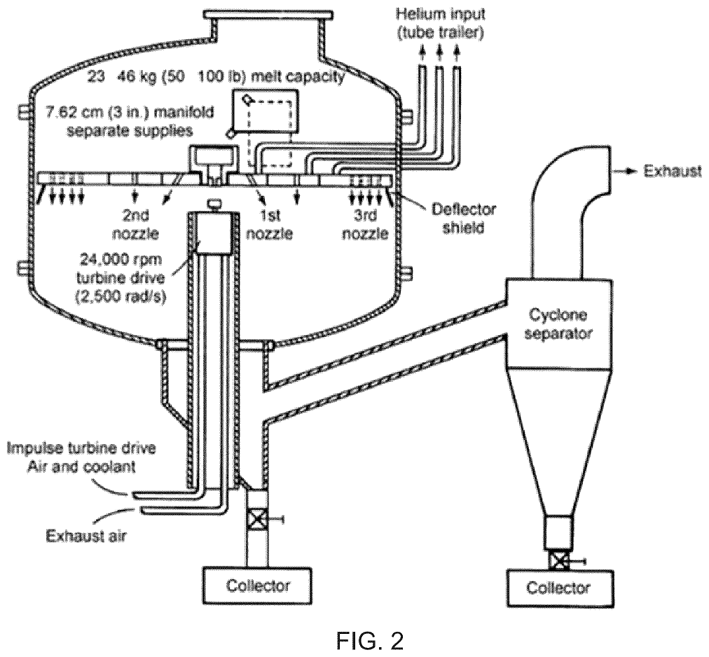

Three pre-alloyed powders with nominal compositions of 5 at %, 30 at %, and 50 at % Sc—Al were manufactured via centrifugal Helium atomization (GA). A schematic of a system is shown in FIG. 2. The starting charge materials of distilled Sc strips (purity of 3N) and Al rods (purity of 5N) were vacuum induction melted with a “tilt-pour” utilizing two refractories. Crucible contamination was found to be mainly from Mg, Si, which was controlled to be at most 400 ppm, and a final total metallic impurity of GA powder was observed to be at most 800 ppm. Control of oxygen is another important consideration in any powder making operation. Oxygen levels of GA powders for three Sc compositions at different stages are listed in Table 1.

TABLE 1
Oxygen contents for three compositional
GA powders at different stages.

| Oxygen (ppm) | AlSc5 | AlSc30 | AlSc50 |
|---|---|---|---|
| GA on site | n/a | 226 | n/a |
| As received | 156 | 1597 | 800-1300 |
| Exposed to air | 340 | 2037 | 5888 |

It can be seen from Table 1 that the oxygen level increased with Sc content, and then leveling off after exposed to air for a long period of time. Oxidization was stopped when the surface of powder was fully covered with oxides. EDS work indicated the oxide was mainly Sc₂O₃, rather than Al₂O₃. 5% Sc—Al GA powder had a considerably lower oxygen content due probably to its much lower melting point, as well as less reactive nature than high Sc alloys, and therefore least crucible reaction at melting, and least oxidization reactions in the whole process.

The atomized powder may be crushed and/or milled to reduce particle size. For example, after atomization, the collected powders were sieved to 100mesh (5% Sc and 30% Sc), and −200 mesh (50% Sc), respectively. One of reasons for high oxygen level from 50% Sc powder when exposed to air is its smaller particle size (−200 mesh) vs-100 mesh for both 5% Sc and 30% Sc. The smaller the particle size, the higher heat exchange efficiency (sintering effect), and the finer the structure, but the concomitant increase in oxygen is a concern. Considering the tradeoff between the two, it is recommended the particle size be −100 mesh (around 150 microns).

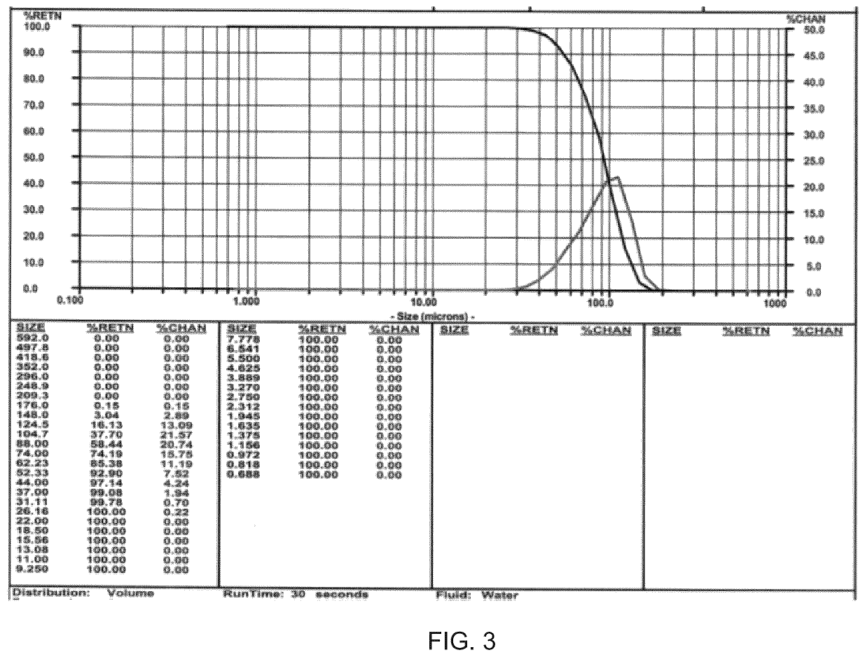

Particle size distribution (PSD) as measured through laser scattering for GA 30% is shown in FIG. 3. PSD is narrow with a D₅₀=90-100 microns. For spherical particles, good flowability can be expected.

The GA powders were sintered by inert gas hot pressing (IGHP) and spark plasma sintering (SPS) as well. Powder handling was performed in a glove box filled with Ar, moisture and oxygen was controlled to be at most 5 ppm. HP was done in-house in an Ar atmosphere using graphite tool set with BN coating around and graphite foils covered top and bottom of the powder. SPS was operated with pulsed DC current. Specimens were processed in a graphite tool set. The thermal cycle involved heating the powder to set temperature to 1000° C. to 1100° C. with heat rates 10,000-15,000 A at 5,000-7,500 A/min under a vacuum/Ar/H₂ atmosphere and an initial pressure of 6-15 MPa. Samples were then isothermally held at temperature for 10 mins before pressure was ramped to 45-65 MPa. The resultant product was a disc puck 100 mm in dia, and 8 mm in thickness.

Pressed pucks were machined, ground to dia. 75 mm×6 mm′ targets that were deposited by magnetron sputtering under an Ar pressure of 3×10⁻³ mbar with a flow rate of 200 sccm. Before deposition, the process chamber was pumped down to 1×10⁻⁶ mbar. The power density was kept constant at 10 W/cm². The sputtering power was ramped up to 440 W in 3 minutes. Targets were first sputtered for 3 min (test run 1 for arcing and particles); then vented to air, evacuated, run for 12 h (test run 2), and finally run again for 3 min w/o vacuum break (test run 3).

### Gas Atomized (GA) Powder

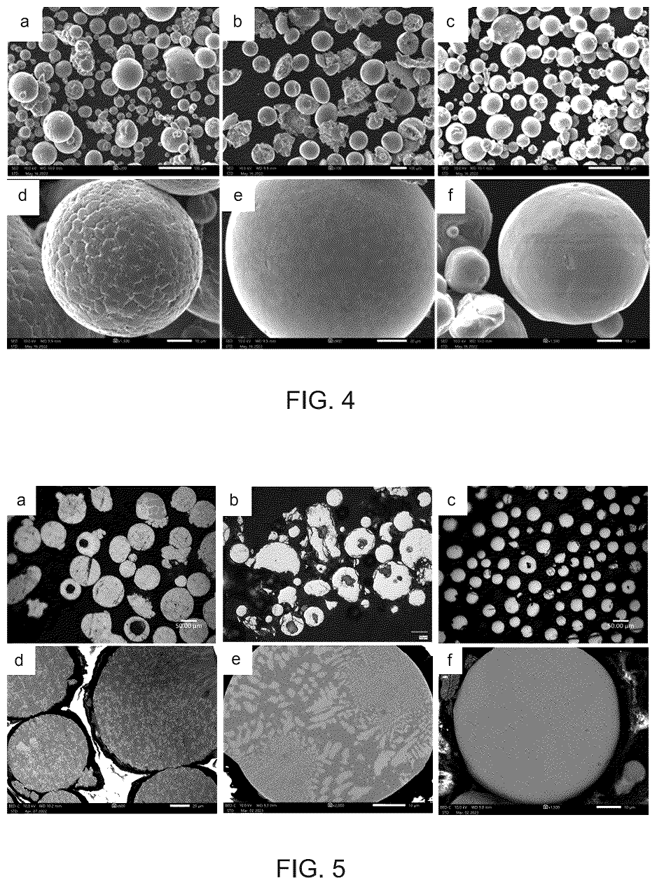

Nearly spherical powder particles are typically produced by various inert gas-typically argon or helium-atomization methods. An inert gas environment protects from oxidation and to promote convective cooling. FIG. 4 shows SEM micrographs of three gas atomized Al—Sc powders. The morphologies of the powders for 5% (FIG. 4a) and 50% (FIG. 4c) are predominantly spherical with some degree of satellite particles. While GA 30% powder has partial non-spherical with a minimum incidence of satellites, there are also some fractured particles (FIG. 4b), both of which could be evidence for a low superheating due to its higher liquidus temperature when the same pour temperature (1410° C.) was utilized for both 30% and Sc₅₀% compositions. Solidification formed non-spherical droplets before they were spheroidized.

As shown in FIG. 4d, the particle surface from GA 5% is not smooth but has a turtle shell-like structure, which is evidence of the solidification showing equiaxed microstructure. FIG. 4e for 30% shows some faint fine artifacts which is believed to be Al₂SC dendrites detailed later. FIG. 4f for GA 50% shows satellite formation.

Cross section images can reveal artifacts that indicate fabrication conditions and possible processing problems. Cross sections of as-atomized powders are shown in FIG. 5. 5% (FIG. 5a) and 30% GA powders (FIG. 5b) show quite a lot of central pores, while 50% powder (FIG. 5c) includes least pores. 30% powder also exhibits quite a lot of pre-exist cracks and voids on edge of particles, which is consistent with the surface morphology revealed in FIG. 4b.

Internal porosities are commonly seen in GA powder particles. During formation of the powder, liquid metal interacts with the inert gas environment, leading to the entrainment of significant levels of gas within the particles. Less pores in 50% powder were possibly contributed to two factors, 1) smaller particle size, and 2) a close to eutectic composition. For the latter, eutectic has a small solidification temperature range, leading to finer inter-dendritic solidification shrinkage and therefore finer voids. Large gas-filled pores are not ideal for consolidation because they are difficult to eliminate by diffusion.

A backscattered electron image reveals the compositional difference. BSE micrographs for 5% (FIG. 5d) and 30% (FIG. 5e) show a two-phased structure. EDS analysis indicated that 5% sample included Al (matrix)+Al₃Sc (white) phases, while 30% sample consisted of Al₂Sc (white dendrite)+Al₃Sc (matrix) phases. The primary Al₃Sc phase in 5% sample exhibits a fine cellular structure (1-2 microns) resulting from the rapid solidification, occasionally big cells (10 microns) were seen. The equiaxed cellular structure is consistent with surface morphology showed in FIG. 4d and is believed to be related to a wide solidification temperature range, ΔT, as indicated in FIG. 6, Al—Sc phase diagram. The first precipitated Al₂Sc phase in 30% sample (FIG. 5e) exhibits dominantly dendrite structures which are believed to be a combination of effects of cool rate, temperature gradient and solidification temperature range. The 30% atomized particle (FIG. 5e) also shows two superfine radial dendrite clusters may be originating from two surface nucleation sites. One possible explanation for the observed microstructure is that the molten drop impacted a solidified small particle which nucleated solidification at the edge, consequently radial dendrites grew outward from the nucleation points. This is a typical example of heterogeneous nucleation.

Cross section of 50% particle (FIG. 5c,f) does not show any artifact of phase structure under both BSE and SED images indicating probably a single-phase structure without a compositional contract.

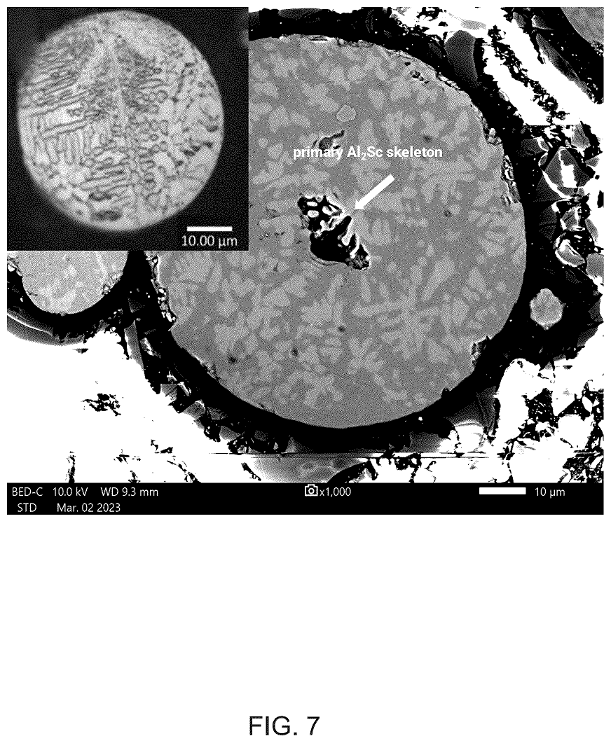

A close examination of dendrites and an inner structure within a central pore from a GA 30% particle can be seen in FIG. 7. A networking skeletal structure inside the central pore is observed, it is clearly evident that the primary Al₂Sc (EDS confirmed) was formed before peritectic reaction could occur. The closed pore prevented liquid phase further access to Al₂Sc dendrite to form Al₃Sc phase.

Dendrite structure is associated with segregation. For GA 30% powder, the dendrite (Al₂Sc) has a higher melting temperature composition as compared to the matrix inter-dendrite regions. The grain size and secondary dendrite arm spacing (DAS) are often used to evaluate segregation/homogenization. Fine DAS and grain size of GA powder are obtained through faster cool and finer particle sizes. From the inset image in FIG. 7, the DAS is measured at 1-2 microns, the solidification time the determines the dendrite arm spacing whereas in general the following principle (Eq. 3-1) applies:

$${t}_{E} = {( \frac{DAS}{A} )}^{3} \qquad ( 3 - 1 )$$

In Eq. 3-1, A represents a material-dependent constant. For a typical aluminum alloy, A=12, so the solidification time is calculated to be 0.58-4.6 mill-seconds. Using solidification temperature range of 100° C., per phase diagram in FIG. 6, the solidify rate is roughly estimated as 2.2×10⁴−1.7×10⁵° C./s. This is two orders faster than that for conventional casting 10-100° C./s, corresponding to a DAS of 30 microns.

Table 2 summarizes the particle size, densities, and flow characteristic for three compositional powders. Lower densities for 5% powder are obviously due mainly to the composition. Density of Sc and Al—Sc intermetallic phases are all close at 3×10³ kg/m³, while aluminum is lighter at 2.7×10³ kg/m³. Hausner ratio for 5% powder is at the same level as others since the density difference from phases is cancelled out. When compared 30% powder with 50%, one can find that their apparent densities are close because all intermetallics have close densities, while 50% powder exhibits a higher tap density and therefore higher Hausner ratio. Higher Hausner ratio indicates that particles undergo a larger density increase with vibration. GA50% powder has a smaller particle size, experiencing a higher interparticle friction, and therefore there is no flow through a Hall flowmeter which is not desirable for most additive manufacturing. Higher tap density may mean better compressibility, where the main factor is pressure. Smaller particles at −200 mesh maybe better than bigger ones at −100 mesh in terms of sintering, however, −100 mesh was chosen for 30% powder consolidation studies when taking oxygen control into consideration.

TABLE 2
Particle size, densities, and flow for three-composition powders.

| | | Apparent | | | |
|---|---|---|---|---|---|
| | Particle | density | Tap density | Hausner | Flow @ |
| | size | (×10³ | (×10³ | ratio | 50 g |
| | (mesh) | kg/m³) | kg/m³) | (Tap/App) | (second) |
| GA 5% | −100 | 1.42 | 1.67 | 1.18 | 54 |
| GA 30% | −100 | 1.71 | 1.91 | 1.12 | 38 |
| GA 50% | −200 | 1.70 | 2.10 | 1.24 | no flow |

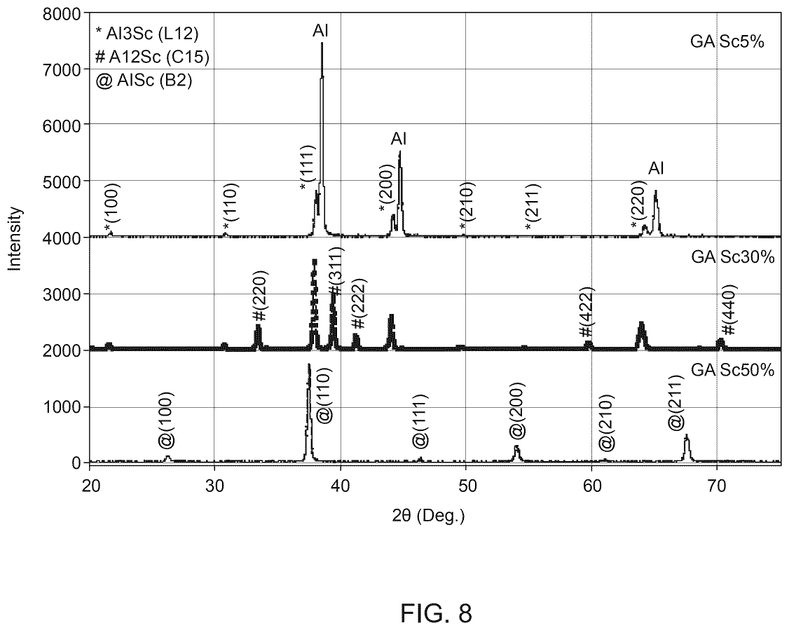

FIG. 8 shows the X-ray diffraction patterns of three GA powders. As indicated in the figure, GA Sc₅% and Sc₃₀% consist of two phases, pure Al+L1₂, and L12+C15, respectively, while GA 50% shows only single B₂ phase. To the best of our knowledge, there is no indexed XRD for Al—Sc system published, especially B₂ structure data is not even included in ICDD reference data base. Therefore, indexing for all Miller indices (hkl) peaks appeared in a 2⊖ range of 20-75° is attempted, as shown in FIG. 8.

Using Eq. (2-3), the lattice parameter constants for each every peak showed are calculated. Table 3 summarizes diffraction index and latter parameter calculation for all three intermetallic phases involved. The calculated lattice parameters of 0.3996 nm, 0.7393 nm and 0.3310 nm for Al₃Sc, Al₂Sc, and AlSc, respectively, are in line with ASM phase diagram data 0.4101 nm, 0.7600 nm, and 0.3388 nm. The consistence of lattice parameter calculation for Al₂Sc confirms the cubic C15 Laves phase, rather than tetragonal C14 structure. The consistence also implies that AlSc is a cubic B2 structure, rather than a tetragonal phase. It is noted further that the variations using different peaks for each phase are small, implying indexing is pretty accurate.

TABLE 3
Summary of diffraction index and latter parameters for three intermetallics.

| | h, k, l | 2θ | θ | 2sinθ | √(h² + K² + L²) | a | Mean |
|---|---|---|---|---|---|---|---|
| Al₃Sc (L1₂) | 100 | 21.701 | 10.8505 | 0.3765 | 1 | 0.399469 | |
| | 110 | 30.886 | 15.443 | 0.5326 | 1.414 | 0.399297 | |
| | 111 | 38.062 | 19.031 | 0.6522 | 1.732 | 0.399406 | |
| | 200 | 44.177 | 22.0885 | 0.7521 | 2 | 0.399947 | |
| | 210 | 49.82 | 24.91 | 0.8424 | 2.236 | 0.39921 | |
| | 220 | 64.174 | 32.087 | 1.0624 | 2.828 | 0.400349 | 0.3996 |
| Al₂Sc (C15) | 220 | 33.466 | 16.733 | 0.5758 | 2.8284 | 0.738783 | |
| | 311 | 39.435 | 19.7175 | 0.6748 | 3.3166 | 0.739207 | |
| | 222 | 41.264 | 20.632 | 0.7047 | 3.4641 | 0.739323 | |
| | 422 | 59.756 | 29.878 | 0.9963 | 4.899 | 0.739546 | |
| | 440 | 70.237 | 35.1185 | 1.1505 | 5.6569 | 0.739503 | 0.7393 |
| AlSc (B₂) | 100 | 26.333 | 13.1665 | 0.4556 | 1 | 0.330114 | |
| | 110 | 37.4 | 18.7 | 0.6412 | 1.414 | 0.331668 | |
| | 111 | 46.39 | 23.195 | 0.7877 | 1.732 | 0.330701 | |
| | 200 | 54.013 | 27.0065 | 0.9082 | 2 | 0.331205 | |
| | 210 | 61.05 | 30.525 | 1.0158 | 2.236 | 0.331064 | |
| | 211 | 67.541 | 33.7705 | 1.1117 | 2.4495 | 0.331389 | 0.3310 |

Bold indexs are fundamental peaks

Superlattice peaks for L1₂ (Al₃Sc) are (100), (110), (210), and (211), while the fundamental peaks (111), (200), (220) are overlapped with those from Al phase in GA Sc₅% powder as shown in FIG. 8. Al has an fcc structure, while L1₂ is an ordered fcc, overlapping indicates the lattice parameters for both phases are close. The mismatch in lattice parameter between Al and Al₃Sc is calculated to be 1.37% at ambient temperature, assuming no residual stresses and taking lattice parameter values of 0.3942 nm and 0.3996 nm for Al and Al₃Sc, respectively. The small mismatch is the basis for precipitation-strengthened Sc-doped aluminum alloys where the precipitated nano-sized L1₂-Al₃SC particles are coherent with the Al matrix due to small mismatch. Since the Al₃Sc/Al interface has high strength, it generates the pinning of dislocation and grain boundary and allows for significant refinement of grains in the castings.

### Consolidation

### Examples 1 & 2. AlSc5% (x=0.05) and AlSc50% (x=0.5)

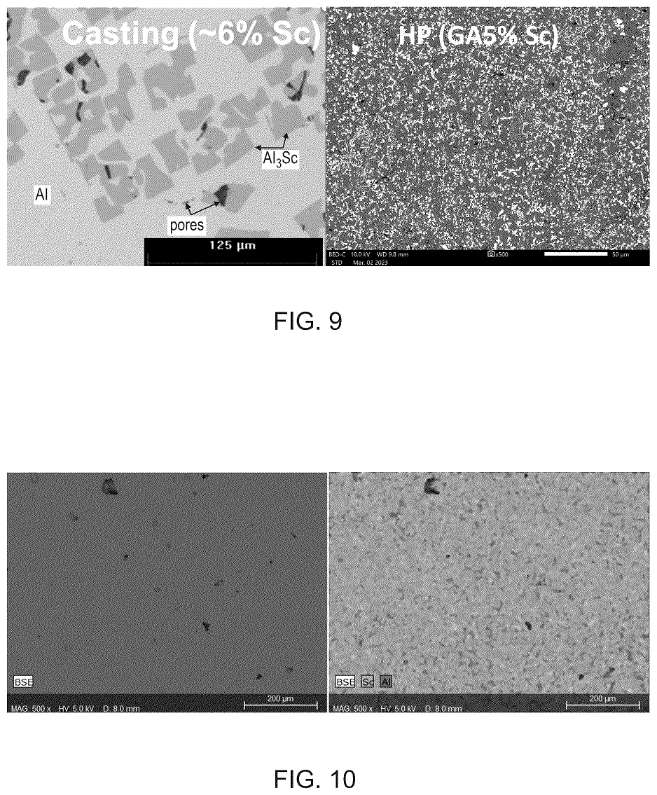

A fully dense (2.77 g/c) target from GA Sc₅% powder was obtained by IGHP at 600° C., 30 MPa. FIG. 9 shows the typical microstructure of Example 1, a pressed sample, at right. Shown for comparison is the as-cast sample, Comparative Example 1 (CE1), at left. The lighter Al₃Sc phase in the hot pressed Example 1 is uniformly distributed in the Al matrix. Example 1 shows a fine microstructure with Al₃Sc average grain size of about 1-3 microns. Comparative Example 1 shows that the Al₃Sc average grain size in the casting is considerably larger (e.g., 10×at least for Example 1) at about 50 microns.

A fully dense (3.07 g/cc) target from GA Sc₅₀% powder was obtained by IGHP at 1100° C., 30 MPa. FIG. 10 shows the typical microstructure of Example 2 (at left) and corresponding EDS elemental mapping (Sc, Al)(at right). As shown, the microstructure of Example 2 is predominantly single-phase B2 AlSc, with few internal pores (appearing black). Elemental mapping (at right) indicates that the distribution of Al and Sc is very uniform within Example 2.

### Example 3. AlSc30% (x=0.3)

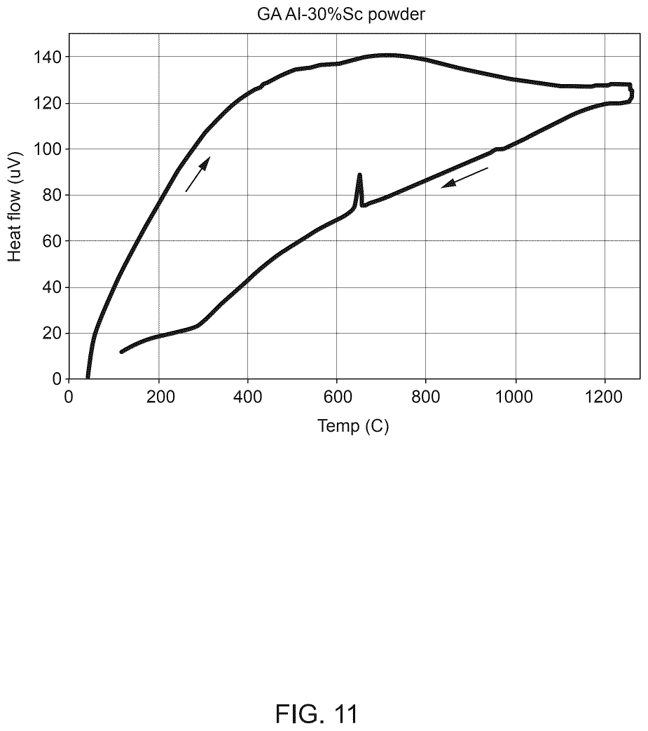

A DTA plot was generated for GA Sc₃₀% as shown in FIG. 11. There is neither exothermic nor endothermic peak present in thermogram at heating, indicating no phase transformation below 1250° C. The broad hump peak of the curve upon heating was likely related to a stress (caused by fast cool at atomization) relief process. No free Al phase was present in the GA 30% powder. Interestingly, the cooling curve shows an endothermic peak of 658° C., which corresponds to Al precipitation. It was unexpected that Al was precipitated at this point because the peritectic temperature is considerably higher (1316° C. per phase diagram) than 1250° C. One possible cause is incipient melting occurred leading to a peritectic reaction, L+Al₂Sc↔Al₃Sc. Based upon the DTA analysis, pressing at temperatures lower than 1250° C. is preferred.

Sputter targets were fabricated using both inert gas hot pressed (IGHP) or spark plasma sintering (SPS). Process parameters and resulting properties are summarized in Table 4. Examples 3.1 to 3.4 were hot pressed, Examples 3.5 to 3.8 were spark plasma sintered, and also included in the table are results from a comparative target, Comparative Example 2 (CE 2), fabricated using conventional melt casting. It can be seen that the optimized temperature and pressure to obtain fully dense targets are similar for both IGHP (Ex. 3.1 to Ex. 3.4) and SPS targets (Ex. 3.5 to Ex. 3.8), although the soak and cycle times for the latter were much shorter. Compared with casting (CE 2), Examples 3.1-3.8 yielded considerably higher electrical conductivity. This is believed to be due to having less pores and finer microstructure. The inventive examples also produced higher hardness, also believed due to the uniform and fine microstructure achieved.

The total metallic impurity was found to be at most 1000 ppm, and oxygen be at most 2000 ppm for all pressed targets. It was observed that both HP and SPS processes did not pick up much oxygen. Fresh atomized 30% Sc powder had low oxygen (<300 ppm), it then increased to at least 1500 ppm (see Table 1) prior to consolidation at collection where No inert atmosphere was protected. It is believed that, under controlled conditions, the final oxygen content could be controlled to at most 1000 ppm, which is the same level as that of casting targets. Table 5 gives a typical impurity analysis as measured for hot pressed Ex. 3.2, with a total metallic impurity content of 793 ppm and oxygen of 1786 ppm.

TABLE 4
A summary of experimental parameters and resulting properties for Example 3.

| | | | | Electrical | | | |
|---|---|---|---|---|---|---|---|
| | Temp (° C.)/ | Press. | | conductivity | Density* | Hardness | O |
| Ex. | Time (min) | (MPa) | Atm. | (%) | (%) | (HV) | (ppm) |
| 3.1 | 1100/240 | 15 | Ar | 16.4 | 95.9 | 278.3 | 1862 |
| 3.2 | 1250/240 | 15 | Ar | 17.8 | 100.3 | 349.6 | 1786 |
| 3.3 | 1100/240 | 45 | Ar | 16.5 | 100.0 | 367.1 | n/a |
| 3.4 | 1000/240 | 45 | Ar | 17.5 | 99.1 | 389.7 | 1700 |
| 3.5 | 1100/10 | 45 | Ar | 17.5 | 98.7 | 357.3 | n/a |
| 3.6 | 1100/22 | 55 | Vacuum | 17.4 | 97.2 | 363.8 | 1580 |
| 3.7 | 1100/40 | 55 | 4.5% H₂ | 17.5 | 99.4 | 361.3 | 1630 |
| 3.8 | 1000/10 | 65 | Vacuum | 17.2 | 99.3 | 367.5 | 1550 |
| CE 2 | | | | 13.7 | 99.2 | 338.8 | 1200 |

*Theoretical density:
3.03 g/cc

TABLE 5
Typical GDMS and LECO results for metallic and gas impurities.
GDMS (PPM)

| Li | Be | B | F | Na | Mg | Al | Si | P | S |
|---|---|---|---|---|---|---|---|---|---|
| 0.031 | 0.448 | 12.47 | 0.651 | 0.983 | 97.07 | 71.53 | 135.945 | 38.378 | 155.902 |
| Cl | K | Ca | Sc | Ti | V | Cr | Mn | Fe | Co |
| 0 | 0.003 | 3.856 | 28.47 | 9.039 | 0.204 | 18.33 | 46.597 | 106.605 | 1.265 |
| Ni | Cu | Zn | Ga | Ge | As | Se | Br | Rb | Sr |
| 31.772 | 19.024 | 1.015 | 1.373 | 0.026 | 0.066 | 0 | 0 | 0.007 | 0.014 |
| Y | Zr | Nb | Mo | Ru | Rh | Pd | Ag | Cd | In |
| 2.711 | 6.993 | 0.298 | 1.295 | 0 | 0 | 0.13 | 0.558 | 0.03 | 0.646 |
| Sn | Sb | Te | I | Cs | Ba | La | Ce | Pr | Nd |
| 0.97 | 0.052 | 0.004 | 0.008 | 0.001 | 0.03 | 1.596 | 3.548 | 0.304 | 0.945 |
| Sm | Eu | Gd | Tb | Dy | Ho | Er | Tm | Yb | Lu |
| 0.003 | 0.001 | 0.259 | 0 | 0 | 0.172 | 0 | 0.035 | 0.019 | 2.178 |
| Hf | Ta | W | Re | Os | Ir | Pt | Au | Hg | Tl |
| 0.093 | 3.918 | 1.904 | 0.011 | 0 | 0.139 | 3.937 | 6.535 | 0.027 | 0.004 |
| Pb | Bi | Th | U | Total | | | | | |
| 0.477 | 0.114 | 0.335 | 0.017 | 792.901 | | | | | |

LECO (PPM)

| C | O | N | S |
|---|---|---|---|
| 557 | 1786 | 24 | 54 |

### Examples 3.1-3.4. IGHP AlSc30% (x=0.3)

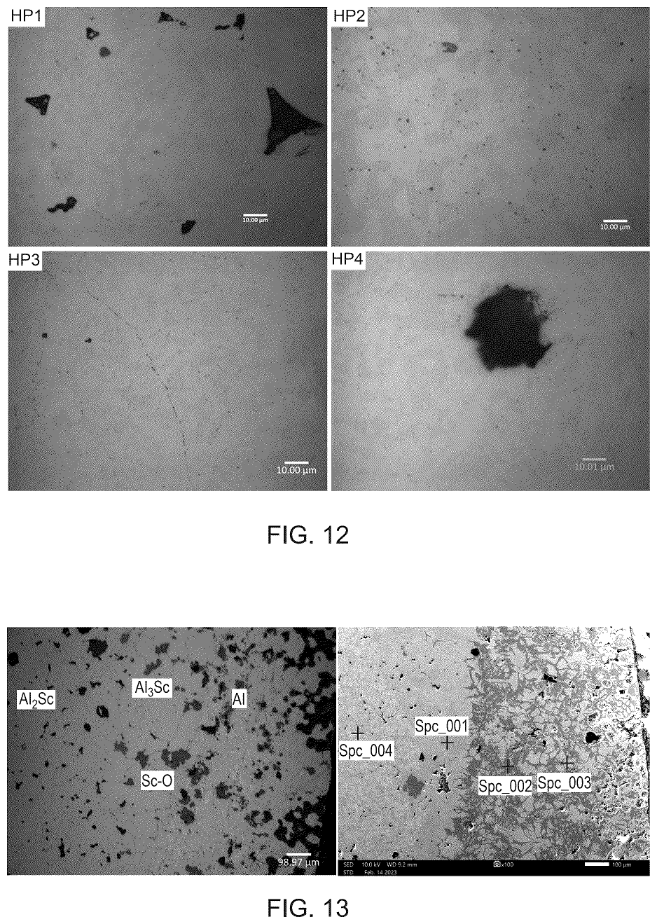

FIG. 12 are optical micrographs showing the microstructure for all four hot pressed Examples 3.1-3.4, having phases Al₂Sc (darker phase) and Al₃Sc (the lighter matrix phase). For the examples pressed at 1000° C. (Ex. 3.4) and 1100° C. (Ex. 3.1 and Ex. 3.3), the amount of Al₂Sc phase remained constant and no obvious coarsening was observed when compared with the starting powder (see FIGS. 5 & 7). When temperature was increased to 1250° C. (Ex. 3.2), however, as shown in FIG. 12 (HP2, Ex. 3.2), regions of the Al₂Sc phase grew appreciably from 1-3 microns in size to 5-10 micron in size. Processing pressure applied played a role also. At a lower pressure of 15 MPa, a large amount of particle boundary pores were not closed (Ex. 3.1) leading to a lower density (95.9%), while at the same temperature of 1100° C., and a higher pressure of 45 MPa (Ex. 3.3), a fully dense target was obtained. In the range of temperatures and pressures employed as in Table 4, porosity (shown as black, e.g., in Ex. 3.4) persisted in all hot pressed examples, Ex. 3.1-3.4, using IGHP.

Although thermal analysis (FIG. 8) indicated that some Al precipitated during cooling after being heated to 1250° C., no free Al phase was detected even when hot pressed at the highest temperature of 1250° C. (Ex. 3.2). Since hot pressing was a slow cooling process, it is believed that a small amount of any precipitated Al may have reacted with Al₂Sc to form Al₃Sc. To confirm that, Ex. 3.1 was further heat treated at 1200° C. for 2 hours (Ex. 3.1.1), then water quenched. As shown in FIG. 13, Al was precipitated out but occurred mainly at the edge of sample, where Sc was locally lost due to surface oxidation, thus promoting Al precipitation. In the meanwhile, Al₂Sc phase at surrounding Al phase area was transformed to Al₃Sc, as indicated in the optical micrograph in FIG. 13 (at left), and confirmed by EDS image (at right) where at positions 001 and 003 Al₃Sc was detected, at position 002 Al₂Sc was detected, and at position 002 Al was detected. It should be noted that, surrounding pore areas and in particle boundary areas where defect free energy is higher, most darker Al₂Sc phase was transformed to lighter Al₃Sc (see FIG. 12, HP 1, 3, and 4 corresponding to Examples 3.1, 3.3, and 3.4, respectively).

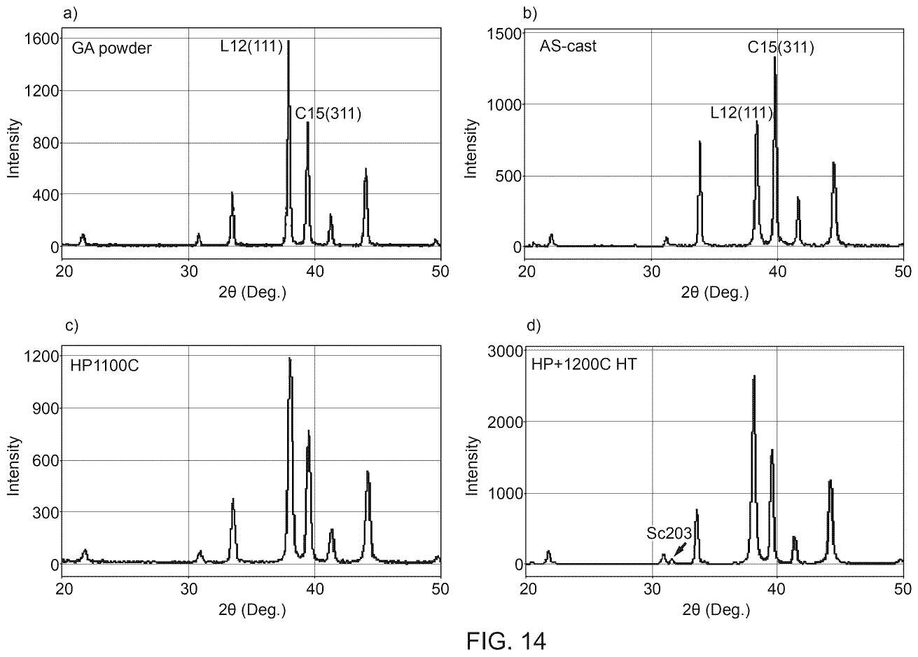

The change of phase amount ratio of Al₃Sc/Al₂Sc at different process stages is evidenced by peak density changes shown the XRD plots as shown in FIG. 14 for gas atomized power (FIG. 14a), the as-cast comparative example (CE2)(FIG. 14b), hot pressed Ex. 3.1 (FIG. 14c), and heat treated hot pressed Ex. 3.1.1 (FIG. 14d). FIG. 14b shows that the primary phase the as-cast comparative example was Al₂Sc (C15), while in inventive GA powder and HP samples, as in FIG. 14a and FIG. 14c, the primary phase present was Al₃Sc (L1₂), as observed by the intensity changes from the peaks for phases L1₂ (111) and C15 (311). This is an important and unexpected finding that the primary phase be Al₃Sc at the scandium content of x=0.30 (or higher) as in Example 3. At this high amount of scandium, the primary phase would be expected to be (according to the phase diagram at FIG. 6) Al₂Sc as was found in the comparative examples. The unexpectedly higher Al₃Sc content of the inventive examples provides for a higher fracture toughness, thereby providing a higher resistance to cracking to ensure long life for the targets prepared according to processes herein. For purposes herein, the primary phase is the phase present in the highest amount by intensity. In addition, a small Sc₂O₃ peak was identified in the heat treated sample as in FIG. 14d, which is consistent with microstructure studies (in FIG. 13 (at left) the dark gray phase is scandium oxide). Free Al was not detected by X-ray diffraction indicating that, if present at all, aluminum metal would be present in an amount of at most 3% by weight due to detection limits of the method.

Phase ratio analysis was performed by determining the integrated intensity, as well as peak height, of the strongest peaks from both phases L1₂ (111) and C15 (311). The phase intensity ratio changes for casting (comparative example) and HP samples at different conditions are summarized in Table 6. As-atomized powder has considerable higher amount Al₃Sc (L1₂) than as-cast. HP at 1100° C. did not change the phase amount ratio, while heat treatment at 1200° C. (Ex. 3.1.2) further increase a bit the amount of Al₃SC phase, which is consistent with the previous results (FIG. 13).

Per the lever rule, the Al₃Sc phase and Al₂Sc phase will be 39.8 at %, and 60.2 at %, respectively, in an equilibrium phase diagram. Atomization was a fast cool process, less primary Al₂Sc formed, before more remained liquid phase took a peritectic reaction with Al₂Sc phase to form more AlsSc phase, leading to a higher Al₃Sc/(Al₃Sc+Al₂Sc) ratio.

TABLE 6
A summary of intensity ratio changes based
on integrate intensity and peak height.

| | Intensity Ratio: Al₃Sc/(Al₃Sc + Al₂Sc) | |
|---|---|---|
| | Integral intensity (Cps Deg) | Height (Cps) |
| As cast (CE2) | 46.30% | 37.50% |
| As gas atomized | 62.30% | 62.40% |
| HP 1100C (Ex. 3.1) | 63.40% | 59.00% |
| HP + 1200C HT (Ex. 3.1.1) | 65.80% | 61.30% |

### Examples 3.5-3.8. SPS AlSc30% (x=0.3)

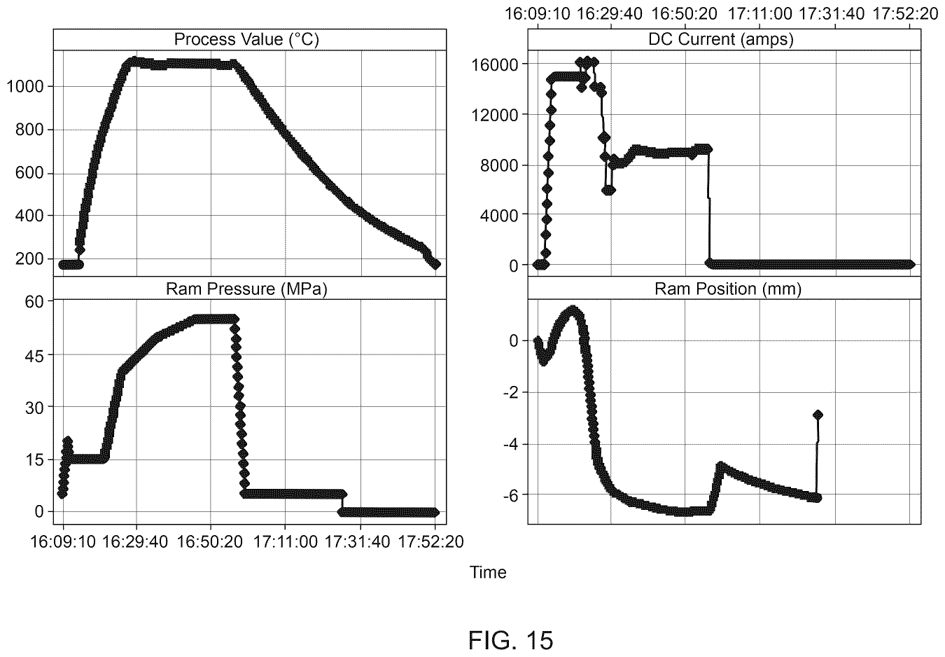

FIG. 15 illustrates s spark plasma sintering process control. A starting pressure of 15 MPa with a pre-compaction aided in densification. Final temperature and holding time were 1100° C. and 22 min. Cooling rate was 15.9° C./min. The total cycle time was at most 2 hours. Notably, the process time of at most 2 hours via spark plasma sintering was significantly shorter than the typical 12 to 24 hours using conventional hot pressing processes. SPS also used shorter processing times as compared to the IGHP as described for Examples 3.1-3.4 above.

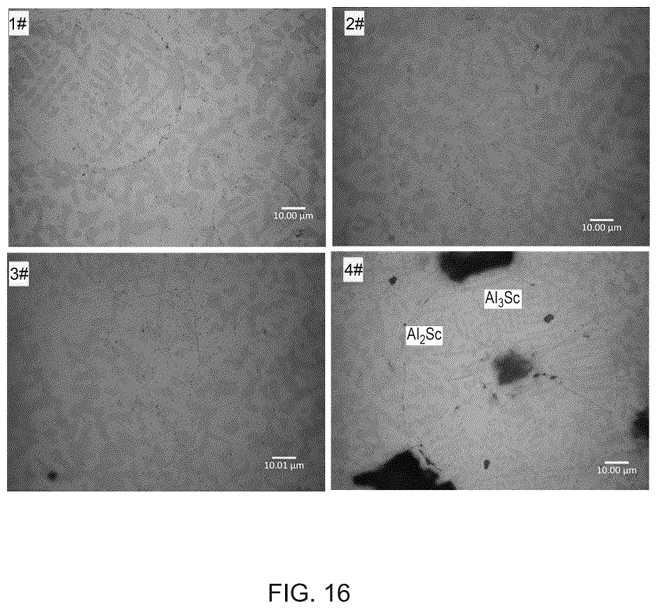

FIG. 16 shows the microstructure for Examples 3.5-3.8 as referred to in Table 4 with Ex. 3.5 at upper left, Ex. 3.6 at upper right, Ex. 3.7 at lower left, and Ex. 3.8 at lower right. Surprisingly, the sintering temperature (1000° C. vs 1100° C.) and time (10 min to 40 min) did not significantly affect phase region size and final density (see Table 4). Increasing the pressing pressure from 45 MPa, to 55 MPa, to 65 MPa also did not impact the properties significantly. However, it was observed that using SPS enabled lower temperatures and shorter times (than hot pressing) while maintaining the fine microstructure. Ex. 3.8, sintered at 1000° C. exhibited particle boundary pores while having the same density as Ex. 3.5-Ex. 3.7 targets sintered at the higher temperature of 1100° C. Oxide particles, shown as black dots in FIG. 16, are sub-micron, e.g., at most 0.2 μm, mainly dispersed in particle boundaries.

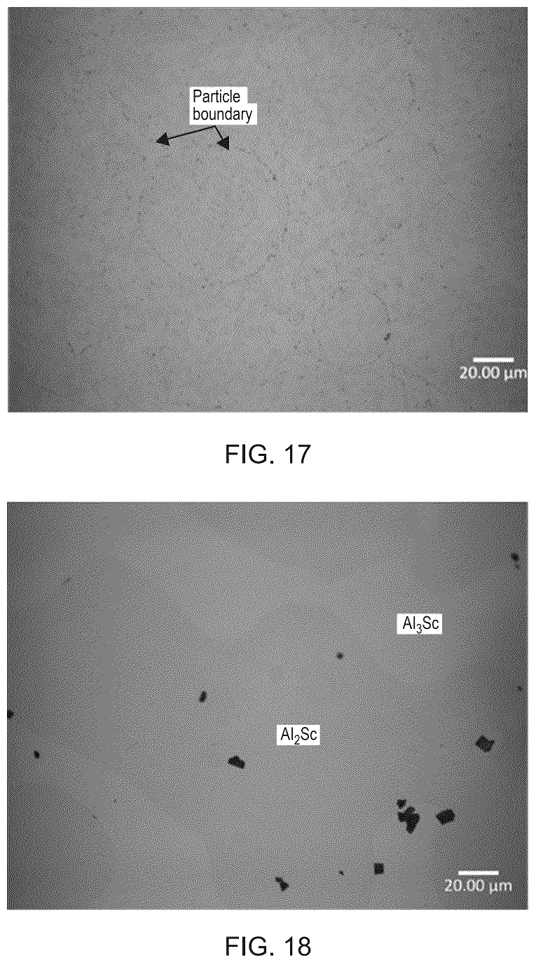

FIG. 17 demonstrates the uniform microstructure and phase morphology for EX.3.5. FIG. 17 shows that Ex. 3.5 exhibits darker Al₂Sc and lighter Al₃Sc phases and demonstrates a fine microstructure with uniform distribution of phases.

By comparison, a conventional as-cast target CE2 is shown in FIG. 18. The CE2 as-cast target example shows large regions (e.g., at least 200 microns) of darker Al₂Sc phase and large regions (e.g., at least 200 microns) of lighter Al₃Sc phase.

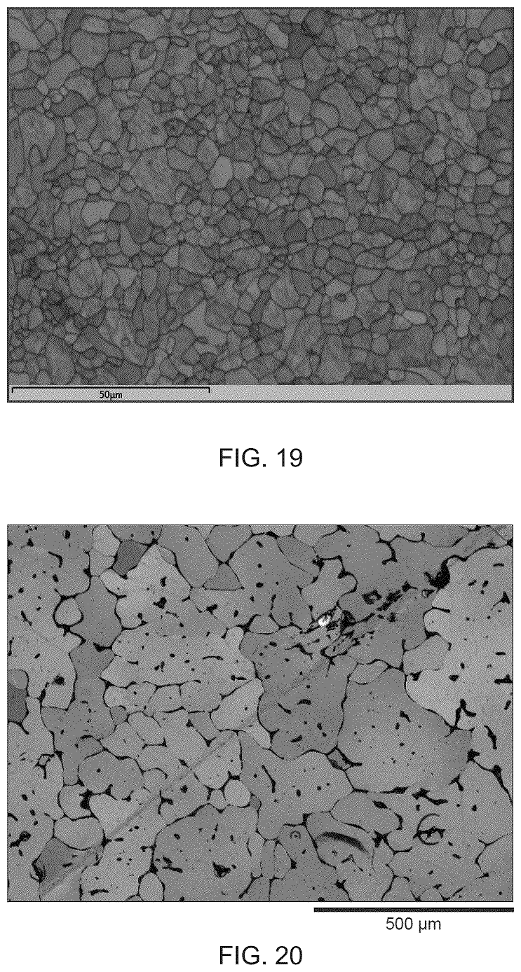

Using electron backscattered diffraction (EBSD) images, FIGS. 19 and 20 show the grain morphologies for Ex. 3.5 and CE2, respectively. FIG. 19 shows that SPS Ex. 3.5 target had an average grain size of about 3.8 microns as calculated by image analysis (equivalent circle, area weighted mean). FIG. 20 shows that the as-cast CE2 target had average grain size in the range of about 200 to 300 microns.

Microhardness data was determined for Ex. 3.5 is shown in Table 7.

TABLE 7
Microhardness Data for Example 3.5.

| | indenter size (μ) | Mean | STDev |
|---|---|---|---|
| HV2 (2 kg load) | 104-112 | 310.8 | 4.6 |
| HV1 (1 kg load) | 70-75 | 347.8 | 9.4 |
| HV0.3 (300 g load) | 37-45 | 343.1 | 31.6 |
| HV0.05 (50 g load) | 14-18 | 356.2 | 25.5 |

Because Vicker's hardness is sensitive to load, the variation (STDev) decreased with increasing load, due at least in part to the indenter size being increased to cover more areas of different phases (Al₃Sc and Al₂Sc). At each load, measurements were made at 5 locations on the surface of the target: four measurements spaced apart along a diameter of the target (two near the perimeter at opposite ends of the diameter) and a fifth measurement perpendicular to the diameter near the perimeter. The hardness was found to be very uniform among these locates. For example, the hardness values for Ex. 3.5 at HV2 (2 kg load) were determined to be 316.8, 308.5, 304.6, 311.2, and 313.1 with a standard deviation of 4.1. The uniform hardness is also indicative of the uniform distribution of phases and fine microstructure of Example 3.5. Whereas cracks may typically form (or lead to failure) during operation using conventional targets (due to thermal shock or flexing due to water pressure used for cooling on a backing plate), the targets herein having the microstructural benefits as described mitigate any cracks. This is due to a higher fracture strength in a more ductile AlSc30% target, and has the added benefit of providing higher sputtering rates.

Example 3.5 was measured by X-ray fluorescence (XRF) for scandium content, also at the five different locations on both the top and bottom surfaces of the target. The chemistry was uniform across the diameter and through the thickness as shown in Table 8. As-cast chemistries as a comparison are shown in International Publication No. WO 2018/169998 A1, incorporated herein by reference.

TABLE 8
Example 3.5 XRF Data.

| XRF | Location | | | | | | |
|---|---|---|---|---|---|---|---|
| (Sc wt %) | 1 | 2 | 3 | 4 | 5 | Mean | STDev |
| Top | 38.50 | 38.14 | 39.08 | 38.3 | 37.93 | 38.39 | 0.36 |
| Bottom | 38.87 | 38.41 | 38.98 | 38.41 | 38.64 | 38.66 | 0.21 |

Electrical conductivity was measured according to ASTM E1004-17 for Ex. 3.5 and data is shown in Table 9. The data show that the electrical conductivity is very uniform and is indicative of uniform scandium distribution and low porosity.

TABLE 9
Example 3.5 Electrical Conductivity Data.

| Elec. | | | | | | | |
|---|---|---|---|---|---|---|---|
| Cond. | Location | | | | | | |
| (% IACS) | 1 | 2 | 3 | 4 | 5 | Mean | STDev |
| Top | 17.40 | 17.44 | 17.42 | 17.39 | 17.43 | 17.416 | 0.019 |
| Bottom | 17.38 | 17.45 | 17.36 | 17.43 | 17.41 | 17.406 | 0.033 |

### Fracture Mechanism for PM 30% Sc

Despite its basic fcc structure, polycrystalline L1₂ (Al₃Sc) is brittle at room temperature. Fracture was found to occur in a transgranular manner by cleavage primarily on {011} planes. Toughness of C15 Al₂Sc Laves phase is even worse due to their usually extreme brittleness at ambient temperatures. 30% Sc consists of both Laves phase and L1₂ brittle phases and is found to crack easily at machining and grinding. Less Laves phase in PM 30% Sc product could be beneficial for cracking resistance.

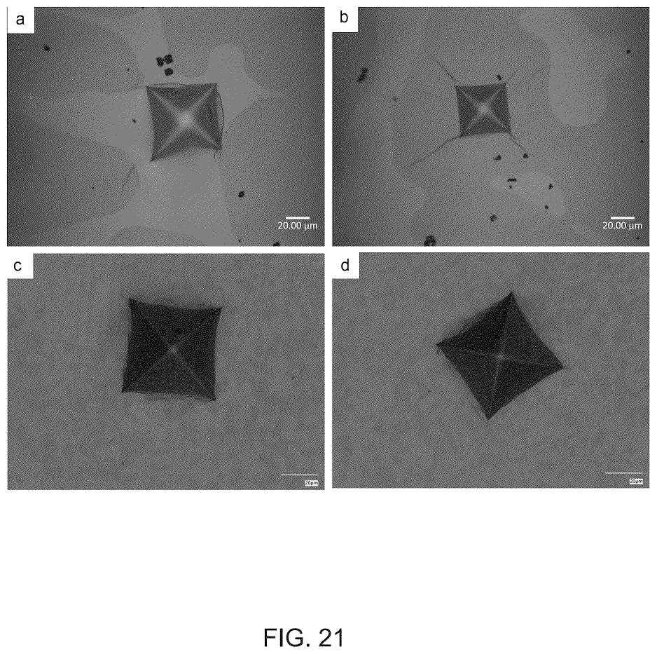

Room-temperature hardness measurements have been used to evaluate the relative strength and ductility of the materials. FIG. 21 compares the Vickers indents from samples made using as-cast (comparative as in FIGS. 21a and 21b), HP (FIG. 21c), and SPS (FIG. 21d). For the as-cast sample, there is a clear difference in indent size and cracking pattern on Al₃Sc (lighter phase) and on Al₂Sc (darker) phase (FIGS. 21a and 21b). Note scale bar length difference. The size of indent on Al₃Sc phase is larger than on Al₂Sc, corresponding to a hardness of 175 HV and 611 HV, respectively, confirming Al₂Sc is more brittle than Al₃Sc. Cracks from Al₂Sc as in FIG. 21b were initialized from four indent corners and propagated (radially) outward. Cracks from Al₃Sc as in FIG. 21a were all associated/connected to Al₂Sc phase, as no cracks were exhibited at any of the corners of the indentation site. Again, this confirms that the Al₂Sc Laves phase is more brittle than Al₃Sc L12 phase.

As shown in FIGS. 21c and 21d, indents size and cracking pattern from HP and SPS (FIGS. 21c and 21d) examples are pretty much the same. Both examples lack long cracks emanating from the indent corners. Instead, they exhibit shorter cracks not only at the corners but also at the sides of indent. The absence of any long propagating cracks emanating from the corners of Vickers indent implies that the PM Sc₃₀% products exhibited a higher fracture toughness than the comparative as-cast products. This is due to the fine and uniform microstructure attained using the processes described herein. Another contributing factor is that less Laves phase is present in PM products (see Table 6). Because there are multiple cracks from each corner and/or uneven crack lengths from as-cast sample, and they lack cracks on the corners from pressed PM samples, it is impossible to quantitatively determine the fracture toughness, K_{1c}, using the Vickers microhardness test.

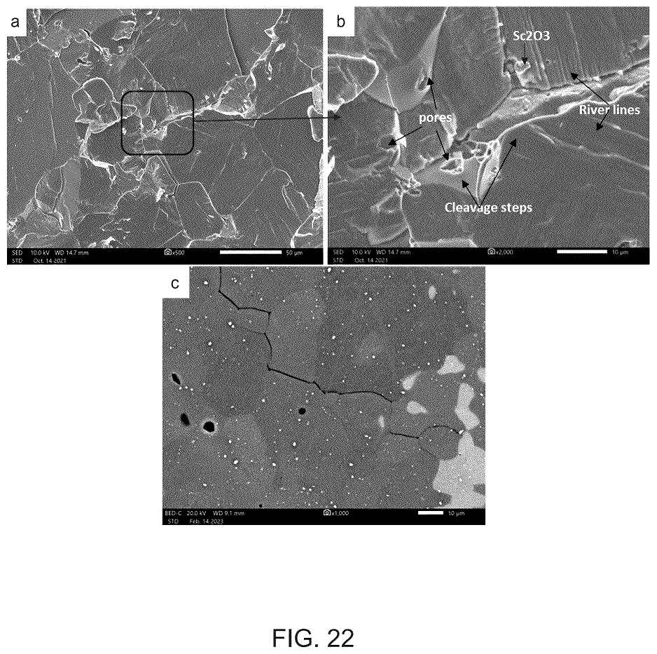

FIG. 22 shows the morphologies of fractured surface caused by bending the SPS Ex. 3.8 and a micrograph showing intergranular cracking induced by thermal stress after water quench. Bended fracture surface is shiny and smooth visually to the naked eye, exhibiting faceted texture because of different orientation of cleavage planes in grains. A typical brittle transgranular fracture showing river lines on transgranular facets at high magnification is shown in FIG. 22b, pointing towards the particle/grain boundaries. Cracks appear to initiate around grain junctions in the center of the image (FIG. 22b), in response to stress concentrations that develop there. Cracks propagate intergranularly as evidence in FIGS. 22a and 22c that the shape and size of grains along fracture path are easy to observe.

### Magnetron Sputtering

A summary of the sputter data is shown in Table 10. HP Ex 3.3 and SPS Ex. 3.8 targets performed much better than as-cast target CE2 after a continuous sputtering run of 12 hours (roughly 33% of the target lifetime), generating fewer micro-arcs and zero hard-arcs.

TABLE 10
Arcing and particle measurements
for As-cast, HP, and SPS targets.

| Target | CE2 | Ex. 3.3 | Ex. 3.8 |
|---|---|---|---|
| micro-arcs after 3 min | 118 | 154 | 7155 |
| hard-arcs after 3 min | 0 | 5 | 8 |
| micro-arcs after 12 h | 343 | 16 | 36 |
| hard-arcs after 12 h | 18 | 0 | 0 |

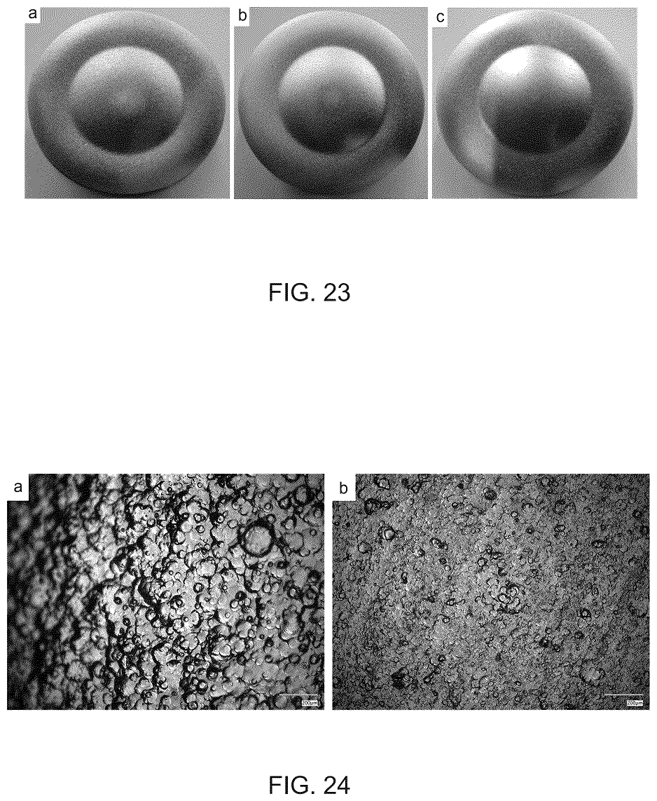

The post-sputtered target is key to better understanding the process. Magnetron sputtering generates a so-called ‘racetrack’ where the plasma (and therefore sputter removal) of the target material is concentrated as shown in FIG. 23. FIG. 23a shows the spent CE2 (as-cast) target; FIG. 23b shows the spent SPS Ex. 3.8 target; and FIG. 23c shows the spent HP Ex. 3.3 target. Ex. 3.3 as in FIG. 23c appears smoother and more reflective than the as-cast CE2 target (FIG. 23a), likely from their intrinsically more uniform and finer microstructures. Comparatively, the surface of SPS Ex. 3.8 is relatively rougher than HP Ex. 3.3 likely due to the presence of inter-particle pores as discussed previously. The post-sputtered targets made by spark plasma sintering and inert gas hot pressing exhibited smoother surfaces relative to the as-cast post-sputtered target. This is indicative of improved sputtering yielding less arcing in the sputtering targets.

A wide range of interacting factors influence magnetron deposition of thin films. These include gas composition, flow rate/pressure, deposition time, deposition rate, power, distance of substrate from target, substrate temperature, electron temperature and the target fabrication process. FIG. 24 shows optical micrographs of the track area (FIG. 24a) of spent SPS Ex. 3.8 target where the plasma is concentrated by the magnetic field, and to an area outside track (FIG. 24b). Track area yielded molten nodules, while outside track area exhibited less pronounced nodular features. The different surface morphologies are a direct result of the localized sputter conditions.

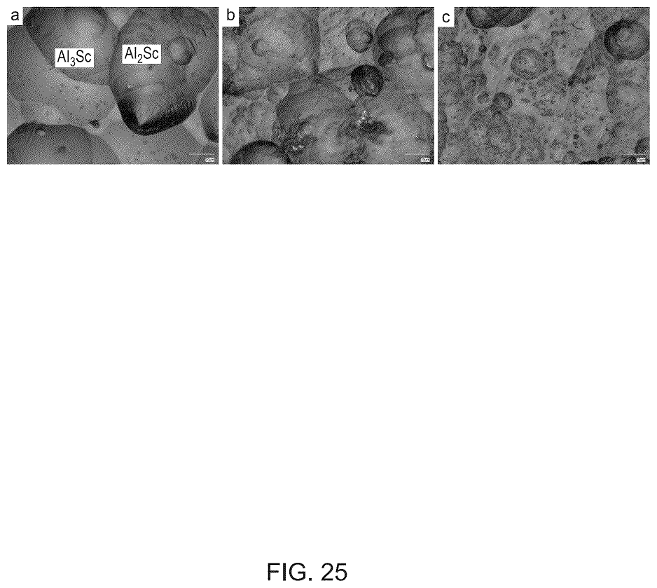

FIG. 25 shows the surface morphologies for three spent targets: CE2 (as-cast) in FIG. 25a, SPS Ex. 3.8 in FIG. 25b, and HP Ex. 3.3 in FIG. 25c. As-cast CE2 target (FIG. 25a) showed a facet structure with bigger nodules. Al₃Sc (lighter phase) and Al₂Sc (darker phase) were smoothly connected and co-existed in the same nodule, which might imply that sputter rate for both phases is similar. SPS Ex. 3.8 and HP Ex. 3.3 targets (FIGS. 25b & 25c) exhibit depleted spherical areas and black dots (possibly oxides). It was observed that the fine, uniform microstructure of the PM targets, e.g., SPS Ex. 3.8 and HP Ex. 3.3 targets, led to less arcing.

### Example 4. HP AlSc35% (x=0.35)

Example 4, a target having composition Al-35% Sc, was prepared. Ingots were crushed and ball milled to-100 mesh powder. The powder was then hot pressed under 1100° C. for 4 hours at 45 MPa/Ar (using the same parameters as Ex.3.3) to a dia. 100 mm and thickness of 8 mm target.

Comparative Example 3 (CE3), a net shaped target with a composition of Al-35% Sc, was vacuum induction melted and casted in a horizontal graphite mold.

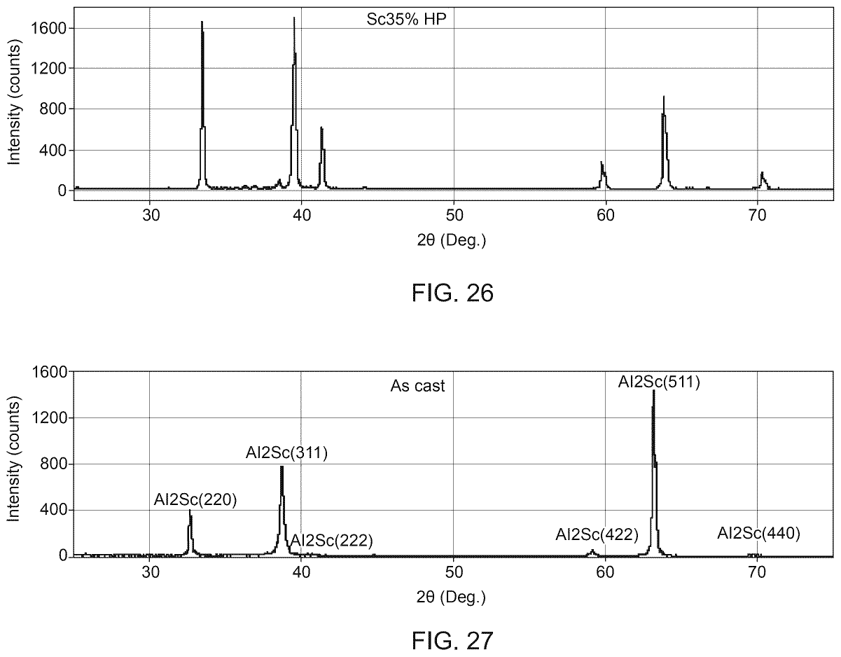

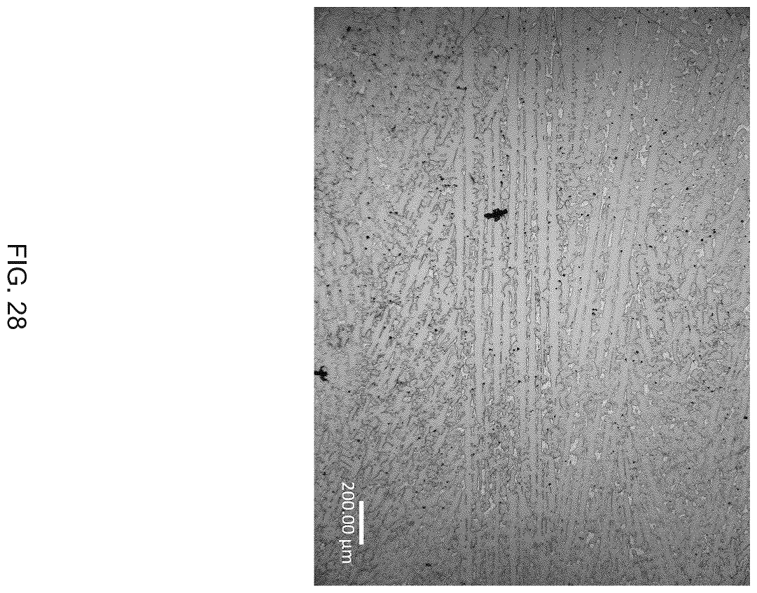

FIGS. 26 and 27 are X-ray diffraction (XRD) plots for Ex. 4 and CE3, respectively. The plots demonstrate that Example 4 exhibits an isotropic texture. In contrast, the as-cast comparative CE3 exhibits a strong (511) texture. The isotropic texture of Ex. 4 imparts benefits in terms of forming thin films using the targets of the invention to provide a uniform sputtering rate and thin film uniformity.

The microstructure of CE3 is shown in optical micrograph FIG. 28, which shows a columnar structure for the as-cast 35% Sc comparative target. The presence of a columnar grain structure is due to the influence of a large temperature gradient during solidification, which results in orientation of the grains, thus confirming that CE3 does not have an isotropic texture.

Although specific terms are used in the following description for the sake of clarity, these terms are intended to refer only to the particular structure of the embodiments selected for illustration in the drawings, and are not intended to define or limit the scope of the disclosure. In the drawings and the following description below, it is to be understood that like numeric designations refer to components of like function.

The singular forms “a,” “an,” and “the” include plural referents unless the context clearly dictates otherwise.

As used in the specification and in the claims, the term “comprising” may include the embodiments “consisting of” and “consisting essentially of.” The terms “comprise(s),” “include(s),” “having,” “has,” “can,” “contain(s),” and variants thereof, as used herein, are intended to be open-ended transitional phrases, terms, or words that require the presence of the named ingredients/components/steps and permit the presence of other ingredients/components/steps. However, such description should be construed as also describing compositions, articles, or processes as “consisting of” and “consisting essentially of” the enumerated ingredients/components/steps, which allows the presence of only the named ingredients/components/steps, along with any impurities that might result therefrom, and excludes other ingredients/components/steps.

Numerical values in the specification and claims of this application should be understood to include numerical values which are the same when reduced to the same number of significant figures and numerical values which differ from the stated value by at most the experimental error of conventional measurement technique of the type described in the present application to determine the value.

All ranges disclosed herein are inclusive of the recited endpoint and independently combinable (for example, the range of “from 2 grams to 10 grams” is inclusive of the endpoints, 2 grams or 10 grams, and all the intermediate values).

As used herein, “at least” and “at most” limits may also include the number associated therewith. Stated another way, “at least” and “at most” may be interpreted as “at least or equal to” and “at most or equal to.” It is contemplated that this language may be subsequently modified in the claims to include “or equal to.” For example, “at least 4.0” may be interpreted as, and subsequently modified in the claims as “at least or equal to 4.0.”

When a material is described as having an average particle size or average particle size distribution, which is defined as the particle diameter at which a cumulative percentage of 50% (by volume) of the total number of particles are attained. In other words, 50% of the particles have a diameter above the average particle size, and 50% of the particles have a diameter below the average particle size. The size distribution of the particles will be Gaussian, with upper and lower quartiles at 25% and 75% of the stated average particle size, and all particles being at most 150% of the stated average particle size.

The process steps described herein refer to temperatures, and, unless provided for, this refers to the temperature attained by the material that is referenced, rather than the temperature at which the heat source (e.g., furnace, oven) is set. The term “room temperature” refers to a range of from 20° C. to 25° C. (68° F. to 77° F.).

The term “about” can be used to include any numerical value that can vary without changing the basic function of that value. When used with a range, “about” also discloses the range defined by the absolute values of the two endpoints, e.g., “about 2 to about 4” also discloses the range “from 2 to 4.” The term “about” may refer to plus or minus 10% of the indicated number.

### Embodiments

The following embodiments are contemplated. All combinations of features and embodiments are contemplated.

Embodiment 1. A process for producing an aluminum-scandium alloy sputtering target, the process comprising: atomizing ScₓAl₁₋ₓ to form a powder, wherein x ranges from 0.05 to 0.5; and consolidating the powder to form a target having a microstructure characterized by an average grain size of at most 50 microns.

Embodiment 2. A process for producing an aluminum-scandium alloy sputtering target, the process comprising: atomizing ScₓAl₁₋ₓ to form a powder, wherein x ranges from 0.25 to 0.45; and consolidating the powder to form a target having a microstructure characterized by an average grain size of at most 50 microns, wherein consolidating includes heating from 900° C. to 1200° C. under pressure by at least one of spark plasma sintering, ultra-high pressure sintering, hot pressing, inert gas hot pressing, and vacuum hot pressing.

Embodiment 3. The process of embodiment 1, wherein x ranges from 0.08 to 0.45.

Embodiment 4. The process of any of embodiments 1-3, wherein the microstructure is characterized by an average grain size of at most 10 microns or at most 5 microns.

Embodiment 5. The process of any of embodiments 1-4, wherein the microstructure is characterized by two or more Al—Sc intermetallic phases distributed in phase regions that are at most 50 microns in diameter, or at most 10 microns in diameter.

Embodiment 6. The process of any of embodiments 1-5, wherein the target has an isotropic texture as determined by X-ray diffraction.

Embodiment 7. The process of any of embodiments 1-6, wherein atomizing includes one or more of: atomizing includes the powder has an Al₃Sc/(Al₃Sc+Al₂Sc) ratio of at least 0.5; atomizing is conducted via centrifugal helium atomization; atomizing forms a powder having at most 1000 ppm oxygen, or at most 600 ppm oxygen, or at most 300 ppm oxygen; atomizing includes further milling the powder to a particle size ranging from 100 microns to 200 microns; and atomizing includes the powder having a particle size distribution, D₅₀, ranging from 90 microns to 100 microns.

Embodiment 8. The process of embodiment 1 or embodiment 2, wherein x ranges from 0.25 to 0.33 and atomizing includes the powder having an Al₃Sc/(Al₃Sc+Al₂Sc) ratio of at least 0.5.

Embodiment 9. The process of any of embodiments 1-8, wherein the powder comprises at most 1000 ppm oxygen and at most 1000 ppm metallic impurities.

Embodiment 10. The process of embodiment 2, wherein the powder comprises at most 300 ppm oxygen.

Embodiment 11. The process of any of embodiments 1-10, wherein the target comprises one or more Al—Sc intermetallic phases; or wherein the target comprises Al₃Sc and Al₂Sc; or wherein the target comprises Al₂Sc and AlSc; or wherein the target is substantially devoid of Al₂O₃ and substantially devoid of free Al.

Embodiment 12. The process of any of embodiments 1-11, wherein x=0.30; or x=0.35; or x=0.38; or x=0.42.

Embodiment 13. An aluminum-scandium alloy sputtering target made according to the process of any of embodiments 1-12.

Embodiment 14. An aluminum-scandium alloy sputtering target comprising one or more Al—Sc intermetallic phases including Al—Sc intermetallic grains, wherein an average Al—Sc intermetallic grain size is at most 50 microns.

Embodiment 15. The aluminum-scandium alloy sputtering target according to embodiment 14, wherein the average Al—Sc intermetallic grain size is at most 10 microns.

While the invention has been described in detail, modifications within the spirit and scope of the invention will be readily apparent to those of skill in the art. In view of the foregoing discussion, relevant knowledge in the art and references discussed above in connection with the Background and Detailed Description, the disclosures of which are all incorporated herein by reference. In addition, it should be understood that aspects of the invention and portions of various embodiments and various features recited below and/or in the appended claims may be combined or interchanged either in whole or in part. In the foregoing descriptions of the various embodiments, those embodiments which refer to another embodiment may be appropriately combined with other embodiments as will be appreciated by one of skill in the art. Furthermore, those of ordinary skill in the art will appreciate that the foregoing description is by way of example only, and is not intended to limit.

1. A process for producing an aluminum-scandium alloy sputtering target, the process comprising:
atomizing ScₓAl₁₋ₓ to form a powder, wherein x ranges from 0.05 to 0.5; and
consolidating the powder to form a target having a microstructure characterized by an average grain size of at most 50 microns.

2. The process of claim 1,
wherein x ranges from 0.08 to 0.45.

3. The process of claim 1, wherein x ranges from 0.25 to 0.45.

4. The process of claim 1, wherein the microstructure is characterized by an average grain size of at most 10 microns.

5. The process of claim 1, wherein the microstructure is characterized by two or more Al—Sc intermetallic phases distributed in phase regions that are at most 50 microns in diameter.

6. The process of claim 1, wherein the target has an isotropic texture as determined by X-ray diffraction.

7. The process of claim 1, wherein atomizing includes one or more of:
atomizing includes the powder has an Al₃Sc/(Al₃Sc+Al₂Sc) ratio of at least 0.5;
atomizing is conducted via centrifugal helium atomization;
atomizing forms a powder having at most 1000 ppm oxygen;
atomizing includes further milling the powder to a particle size ranging from 100 microns to 200 microns; and
atomizing includes the powder having a particle size distribution, D₅₀, ranging from 90 microns to 100 microns.

8. The process of claim 1, wherein x ranges from 0.25 to 0.33 and atomizing includes the powder having an AlsSc/(Al₃Sc+Al₂Sc) ratio of at least 0.5.

9. The process of claim 1, wherein the powder comprises at most 1000 ppm oxygen and at most 1000 ppm metallic impurities.

10. The process of claim 7, wherein the powder comprises at most 300 ppm oxygen.

11. The process of claim 1, wherein the target comprises one or more Al—Sc intermetallic phases.

12. The process of claim 1, wherein x=0.30; or x=0.35; or x=0.38; or x=0.42.

13. An aluminum-scandium alloy sputtering target made according to the process of claim 1.

14. An aluminum-scandium alloy sputtering target comprising one or more Al—Sc intermetallic phases including Al—Sc intermetallic grains, wherein an average Al—Sc intermetallic grain size is at most 50 microns.

15. The aluminum-scandium alloy sputtering target of claim 14, wherein the average Al—Sc intermetallic grain size is at most 10 microns.

16. The process of claim 1, wherein the target comprises AlsSc and Al₂Sc.

17. The process of claim 1, wherein the target comprises Al₂Sc and Al₂Sc.

18. The process of claim 1, wherein the target is substantially devoid of Al₂O₃ and substantially devoid of free Al.

19. A process for producing an aluminum-scandium alloy sputtering target, the process comprising:
atomizing ScₓAl₁₋ₓ to form a powder, wherein x ranges from 0.25 to 0.45; and
consolidating the powder to form a target having a microstructure characterized by an average grain size of at most 50 microns, wherein consolidating includes heating from 900° C. to 1200° C. under pressure by at least one of spark plasma sintering, ultra-high pressure sintering, hot pressing, inert gas hot pressing, and vacuum hot pressing.

20. The process of claim 19, wherein the powder comprises at most 300 ppm oxygen.
